(19) United States
(12) Patent Application Publication
(10) Pub. No.: US 2024/0319542 A1
(43) Pub. Date: Sep. 26, 2024

(54) EXPOSURE SYSTEM, METHOD OF FORMING ALIGNMENT FILM, METHOD OF MANUFACTURING OPTICAL ELEMENT, AND OPTICAL ELEMENT

(71) Applicant: FUJIFILM Corporation, Tokyo (JP)

(72) Inventors: Masao MORI, Saitama-shi (JP); Yu KITAHARA, Saitama-shi (JP)

(73) Assignee: FUJIFILM Corporation, Tokyo (JP)

(21) Appl. No.: 18/680,430

(22) Filed: May 31, 2024

Related U.S. Application Data
(63) Continuation of application No. PCT/JP2022/044588, filed on Dec. 2, 2022.

(30) Foreign Application Priority Data
Dec. 3, 2021 (JP) 2021-196954
Nov. 30, 2022 (JP) 2022-191427

(51) Int. Cl. G02F 1/1337; G02F 1/29; G03F 7/00

(52) U.S. Cl. CPC G02F 1/133757; G02F 1/294; G03F 7/70225

(57) ABSTRACT

Provided are an exposure system that simply manufactures an alignment film corresponding to an optical element where a focal length continuously changes, a method of forming an alignment film using the exposure system, a method of manufacturing an optical element using the alignment film, and an optical element. The exposure system includes: a light source; a beam splitter that splits light emitted from the light source; a beam combiner that combines the light split by the beam splitter and includes a first surface allowing transmission of light and a second surface reflecting light; focusing elements that is provided upstream of the beam combiner; and a polarization conversion element, in which one or more of the focusing elements have a focal length continuously changes in a direction orthogonal to an optical axis and away from the optical axis, and a ratio of a maximum value to a minimum value of the focal length is more than 1.1.

### CROSS-REFERENCE TO RELATED APPLICATIONS

This application is a Continuation of PCT International Application No. PCT/JP2022/044588 filed on Dec. 2, 2022, which claims priority under 35 U.S.C. § 119(a) to Japanese Patent Application No. 2021-196954 filed on Dec. 3, 2021 and Japanese Patent Application No. 2022-191427 filed on Nov. 30, 2022. The above applications are hereby expressly incorporated by reference, in their entirety, into the present application.

### BACKGROUND OF THE INVENTION

### 1. Field of the Invention

The present invention relates to an exposure system that generates interference light, a method of forming an alignment film using the exposure system, a method of manufacturing an optical element using the alignment film, and an optical element.

### 2. Description of the Related Art

An optical element that controls a direction of light is used in many optical systems.

For example, the optical element that controls a direction of light is used in various optical devices, for example, a backlight of a liquid crystal display device, a head-mounted display (HMD) such as Augmented Reality (AR) glasses that display a virtual image, various information, or the like to be superimposed on a scene that is actually being seen or Virtual Reality (VR) goggles that display an artificially-created virtual space as real, a projector, a beam steering device, or a sensor for detecting a thing or measuring the distance to a thing.

In order to install the optical element that controls a direction of light in various systems, applications, and the like, the optical element is required to bend light in various directions depending on uses. In order to achieve the object, an optical element where a focal length varies in a plane, that is, in a direction orthogonal to an optical axis is disclosed.

For example, Junyu Zou et al., Doubling the optical efficiency of VR systems with a directional backlight and a diffractive deflection film, Vol. 29, No. 13/21 Jun. 2021/Optics Express 20673 and US2020/0371475A disclose an optical element (liquid crystal diffractive lens) having a concentric liquid crystal alignment pattern where a liquid crystal compound that is aligned such that an optical axis continuously rotates in one direction is radially provided, in which the optical element includes regions where a focal length varies in a plane.

In the optical element having a liquid crystal alignment pattern where an optical axis derived from the liquid crystal compound rotates in one direction, in a case where a distance over which the optical axis rotates by 180° in the one direction is set as a single period, diffraction of light increases as the single period decreases.

Accordingly, in the optical element having the above-described concentric liquid crystal alignment pattern, the single period gradually decreases from the inner side (optical axis) toward the outer side. As a result, the optical element acts as a condenser lens or a divergent lens. In addition, in the optical element, as the single period decreases, the diffraction increases, and thus the focal length decreases.

Here, in the typical optical element (liquid crystal diffractive lens), a decrease in the length of the single period is an inverse-proportional monotonic decrease, and the focal length is substantially constant over the entire surface in a plane, that is, in the direction orthogonal to the optical axis.

On the other hand, by controlling the degree of the decrease in the length of the single period, the regions where the focal length varies in a plane of the optical element can be formed.

The optical element is typically manufactured by forming an alignment film having an alignment pattern corresponding to a liquid crystal alignment pattern and forming an optically-anisotropic layer including a liquid crystal compound on the alignment film.

Accordingly, in order to manufacture an optical element having desired optical characteristics, it is necessary to form an alignment pattern corresponding to a liquid crystal alignment pattern for realizing desired optical characteristics on the alignment film.

In order to form the alignment pattern, a photo-alignment film for forming the alignment pattern by light irradiation, that is, exposure is suitably used.

As a method of forming the alignment pattern including the regions where the focal length varies in a plane in the optical element having the concentric liquid crystal alignment pattern, that is, in the photo-alignment film for forming the optical element, a direct drawing exposure method described in JP2015-532468A and Jihwan Kim et al., Fabrication of ideal geometric-phase holograms with arbitrary wavefronts, Optica Vol. 2, Issue 11, pp. 958-964 (2015) and an exposure method using a mask described in JP2010-525395A and Junyu Zou et al., Doubling the optical efficiency of VR systems with a directional backlight and a diffractive deflection film, Vol. 29, No. 13/21 Jun. 2021/Optics Express 20673 are known.

### SUMMARY OF THE INVENTION

The direct drawing exposure method is an exposure method in which, as conceptually shown in FIG. 22, a light beam emitted from a light source 100 transmits through a rotatable polarization conversion element 102 (½ wave plate) to be converted into linearly polarized light where a polarization direction rotates, this linearly polarized light is optionally reflected from a mirror 104 to be focused on a condenser lens 106, and is focused on a non-exposed photo-alignment film 110 placed on an x-y stage 108 to expose the photo-alignment film 110. In the example shown in the drawing, the non-exposed photo-alignment film 110 is supported by a glass substrate 112.

In the direct drawing exposure method, by moving the x-y stage 108 to control an incidence position of the light beam in the non-exposed photo-alignment film 110, a desired alignment pattern corresponding to, for example, an optical element that includes regions where the focal length varies in a plane is formed on the non-exposed photo-alignment film 110 (photo-alignment film).

In the direct drawing exposure method, alignment films having various alignment patterns, that is, optical elements having various liquid crystal alignment patterns can be manufactured depending on the purpose with a high degree of freedom. On the other hand, in the direct drawing exposure method, in order to draw the desired pattern, an enormous amount of time is required, and there is a problem in that the productivity is low.

On the other hand, as the exposure method using a mask, JP2010-525395A describes a method in which a birefringence mask corresponding to a liquid crystal alignment pattern to be formed is used, and a non-exposed alignment film is exposed through the mask to form a desired alignment pattern.

In this exposure method, by forming the birefringence mask using the direct drawing exposure method and exposing an alignment film using the birefringence mask to form an alignment pattern, the degree of design freedom and the productivity are simultaneously achieved. On the other hand, in the exposure method, light that cannot be completely bent through the birefringence mask is noise light, and it is difficult to accurately form the alignment pattern.

Further, Junyu Zou et al., Doubling the optical efficiency of VR systems with a directional backlight and a diffractive deflection film, Vol. 29, No. 13/21 Jun. 2021/Optics Express 20673 describes the exposure method using the mask for exposure of an alignment pattern using interference.

In the interference exposure method, light transmitted through a linear polarizer is split into two beams by a polarization beam splitter, and the split beams are converted into circularly polarized light components by a ¼ wave plate. Further, in a state where only one circularly polarized light component is focused through a lens, the two circularly polarized light components are combined to interfere with each other by a beam combiner (beam splitter), and a non-exposed alignment film is exposed to the interference light.

Due to the interference exposure, the above-described concentric alignment pattern can be formed on the alignment film.

Here, the length of the single period in the alignment pattern is determined depending on the focal length of the lens. In the exposure method described in Junyu Zou et al., Doubling the optical efficiency of VR systems with a directional backlight and a diffractive deflection film, Vol. 29, No. 13/21 Jun. 2021/Optics Express 20673, by repeatedly blocking an unnecessary portion with the mask and performing exposure while adjusting the focal length of the lens, an alignment pattern including regions where the focal length varies in a plane is formed.

However, in this exposure method, the regions where the focal length continuously changes in a plane cannot be formed. In addition, in the exposure method, as also described in Junyu Zou et al., Doubling the optical efficiency of VR systems with a directional backlight and a diffractive deflection film, Vol. 29, No. 13/21 Jun. 2021/Optics Express 20673, a non-uniform boundary region is formed between the regions where the focal length varies, and there is a problem in that it is difficult to form an appropriate liquid crystal alignment pattern. The non-uniform boundary region and the disorder of the alignment pattern cause an unnecessary image called a ghost, multiple images, and the like to occur. In particular, recently, the resolution of AR glasses, VR goggles, and the like tends to be improved and the viewing angle tends to be widened. Therefore, in a small boundary region of 150 μm or less, a ghost and multiple images caused by the boundary region cause a problem in image quality.

An object of the present invention is to solve the above-described problem of the related art and to provide an exposure system that can simply form an alignment film for manufacturing an optical element including regions where a focal length continuously changes without including a boundary region, a method of forming an alignment film using the exposure system, a method of manufacturing an optical element using the alignment film, and an optical element that can suppress the occurrence of a ghost and multiple images.

In order to achieve the object, the present invention has the following configurations.
[1] An exposure system comprising:
   a light source;
   a beam splitter element that splits light emitted from the light source;
   a beam combiner element that includes a first surface and a second surface and emits light obtained by combining light transmitted through the first surface and light reflected from the second surface, the first surface allowing incidence of one light component split by the beam splitter element and transmission of at least a part of the incidence light, and the second surface allowing incidence of another light component split by the beam splitter element and reflecting at least a part of the incidence light; and
   a focusing element that focuses light and is provided on at least one of an optical path of first light incident into the first surface of the beam combiner element or an optical path of second light incident into the second surface of the beam combiner element,
   wherein at least one of the focusing elements is a focal point-variable focusing element where a focal length fL continuously changes in a direction orthogonal to an optical axis, and a ratio “fLmax/fLmin” of a maximum value fLmax to a minimum value fLmin of the focal length fL is more than 1.1.
[2] The exposure system according to [1], further comprising:
   a beam expander element that is provided at at least one position of a position between the light source and the beam splitter element, a position between the beam splitter element and the beam combiner element, or a position where light is not focused.
[3] The exposure system according to [1] or [2],
   in which in the focal point-variable focusing element, a profile of the focal length that continuously changes in the direction orthogonal to the optical axis has one or more extreme values.
[4] The exposure system according to any one of [1] to [3],
   in which the focal point-variable focusing element includes a plurality of lenses.
[5] The exposure system according to any one of [1] to [4],
   in which the focal point-variable focusing element includes at least one of an aspherical lens or a cylinder lens.
[6] The exposure system according to any one of [1] to [5],
   wherein in a case where parallel light is incident into the focal point-variable focusing element, at least a part of light emitted from the beam combiner element has an angle of 15° or more with respect to an optical axis of the focal point-variable focusing element.
[7] The exposure system according to any one of [1] to [6],
   in which a ratio maximum value/minimum value of a maximum value to a minimum value of an intensity of light in the direction orthogonal to the optical axis of the focal point-variable focusing element is 25 times or less on an exposure surface.
[8] The exposure system according to any one of [1] to [7],
   in which an optical path length between the beam splitter element and the beam combiner element is 800 mm or less.
[9] The exposure system according to any one of [1] to [8],
   in which one or more optical elements that are present have a surface reflectivity of 0.5% or less with respect to light emitted from the light source.
[10] The exposure system according to any one of [1] to [9],
   in which the light source emits light having a wavelength of 320 to 410 nm.
[11] The exposure system according to any one of [1] to [10], further comprising:
   at least one adjustment unit of an adjustment unit that detects an optical path of light emitted from the light source at a position upstream of the beam splitter element and adjusts the optical path of the light based on a detection result of the optical path of the light or an adjustment unit that detects an interference fringe generated by interference of combined light at a position downstream of the beam combiner element and adjusts an optical path of at least one of light components split by the beam splitter element based on a detection result of the interference fringe.
[12] A method of forming an alignment film, the method comprising:
   exposing a coating film that includes a compound having a photo-aligned group using the exposure system according to any one of [1] to [11].
[13] A method of manufacturing an optical element, the method comprising:
   a step of applying a composition including a liquid crystal compound to an alignment
   film formed using the method of forming an alignment film according to and drying the applied composition.
[14] The method of manufacturing an optical element according to [13],
   in which the composition includes a chiral agent.
[15] An optical element that diffracts incidence light and emits the diffracted light, the optical element comprising:
   a liquid crystal layer that concentrically has a liquid crystal alignment pattern where an orientation of an optical axis derived from a liquid crystal compound changes while continuously rotating in at least one in-plane direction,
   in which in a case where a length over which the orientation of the optical axis derived from the liquid crystal compound in the liquid crystal alignment pattern of the liquid crystal layer rotates by 180° in a plane is set as a single period, a length of the single period in the liquid crystal alignment pattern gradually changes in the one direction,
   in the optical element, a focal length fG continuously changes in a direction from a center toward an outer side of the concentric circle,
   a ratio “fGmax/fGmin” of a maximum value fGmax to a minimum value fGmin of the focal length fG is more than 1.1,
   at a position where a ratio of an intensity of zero-order light to an intensity of first-order light in a plane of the optical element is the maximum, in a case where the ratio of the intensity of the zero-order light to the intensity of the first-order light is represented by Rmax, the ratio Rmax is 3% or less, and
   in a case where a ratio of an intensity of a diffracted light component having a maximum intensity among diffracted light components having diffraction angles less than a diffraction angle of first-order light to an intensity of first-order light is represented by Xmax, the ratio Xmax is 3% or less at a position where the ratio Xmax is the maximum in a plane of the optical element.
[16] The optical element according to [15],
   wherein Δn of the liquid crystal layer is 0.2 to 0.5.
[17] The optical element according to or [16], comprising:
   a plurality of the liquid crystal layers,
   wherein at least two of the liquid crystal layers include regions where tilts of bright and dark lines in cross sectional images obtained by observing cross sections taken in a thickness direction along the one direction with a scanning electron microscope are different from each other.
[18] An optical element according to [17], comprising:
   at least three liquid crystal layers including
   a first liquid crystal layer where the bright and dark lines are tilted with respect to a main surface,
   a second liquid crystal layer where a tilt direction of the bright and dark lines is opposite to that of the first liquid crystal layer, and
   a third liquid crystal layer that is provided between the first liquid crystal layer and the second liquid crystal layer and where an angle of the bright and dark lines with respect to a main surface is more than those of the first liquid crystal layer and the second liquid crystal layer.

In the exposure system according to an aspect of the present invention and the method of forming an alignment film according to an aspect of the present invention, an alignment film for manufacturing an optical element including regions where a focal length continuously changes without including a boundary region can be simply formed. In addition, in the method of manufacturing an optical element and the optical element according to aspects of the present invention, an optical element having a liquid crystal alignment pattern including regions where a focal length continuously changes without including a boundary region and where the occurrence of a ghost and multiple images is suppressed can be simply obtained.

### BRIEF DESCRIPTION OF THE DRAWINGS

FIG. 1 is a diagram conceptually showing an example of an exposure system according to the present invention.

FIG. 2 is a conceptual diagram showing a focal length of a focusing element.

FIG. 3 is a diagram conceptually showing an example of an alignment pattern formed by typical interference exposure.

FIG. 4 is a diagram conceptually showing a focal length profile of a typical focusing element.

FIG. 5 is a diagram conceptually showing a focal length profile of a focusing element according to Example of the present invention and a focal length profile of an optical element manufactured in Example of the present invention.

FIG. 6 is a diagram conceptually showing an example of a focusing element.

FIG. 7 is a plan view conceptually showing an example of an optical element having a concentric liquid crystal alignment pattern.

FIG. 8 is a schematic cross sectional view showing the optical element shown in FIG. 7.

FIG. 9 is a conceptual diagram showing the optical element shown in FIG. 7.

FIG. 10 is a conceptual diagram showing the optical element shown in FIG. 7.

FIG. 11 is a conceptual diagram showing the optical element shown in FIG. 7.

FIG. 12 is a schematic cross sectional view showing another example of the optical element.

FIG. 13 is a conceptual diagram showing the optical element shown in FIG. 12.

FIG. 14 is a conceptual diagram showing the optical element shown in FIG. 12.

FIG. 15 is a conceptual diagram showing the optical element shown in FIG. 12.

FIG. 16 is a conceptual diagram showing a method of measuring a ratio between the focal lengths.

FIG. 17 is a conceptual diagram showing a method of measuring a zero-order light intensity.

FIG. 18 is a conceptual diagram showing a method of measuring a noise light intensity.

FIG. 19 is a diagram conceptually showing another example of the optical element according to the present invention.

FIG. 20 is a diagram conceptually showing a focusing element according to Example of the present invention.

FIG. 21 is a diagram conceptually showing a focal length profile of an optical element manufactured in Comparative Example of the present invention.

FIG. 22 is a conceptual diagram showing a direct drawing exposure method.

### DESCRIPTION OF THE PREFERRED EMBODIMENTS

Hereinafter, an exposure system, a method of forming an alignment film, a method of manufacturing an optical element, and an optical element according to the present invention will be described in detail based on preferred embodiments shown in the accompanying drawings.

The following description regarding configuration requirements has been made based on a representative embodiment of the present invention. However, the present invention is not limited to the embodiment.

Further, all the drawings described below are conceptual views for describing the present invention. A size, a thickness, a positional relationship, and the like of each of members, portions, and the like do not necessarily match with the actual ones.

In the present specification, numerical ranges represented by “to” include numerical values before and after “to” as lower limit values and upper limit values.

FIG. 1 conceptually shows an example of an exposure system according to an embodiment of the present invention.

An exposure system 50 shown in FIG. 1 includes a light source 52, a beam splitter element 54, mirrors 56a and 56b, a focusing element 58, a beam combiner element 60, and a polarization conversion element 62.

In addition, in the exposure system 50, as a preferable aspect, a beam expander element 70 and an optical path adjustment optical system 72 are provided between the light source 52 and the beam splitter element 54. The optical path adjustment optical system 72 is the adjustment unit according to the embodiment of the present invention, detects a light beam M emitted from the light source 52, adjusts an optical path of the light beam M, and includes actuated mirrors 74a and 74b, a mirror 76, and detectors 78a and 78b.

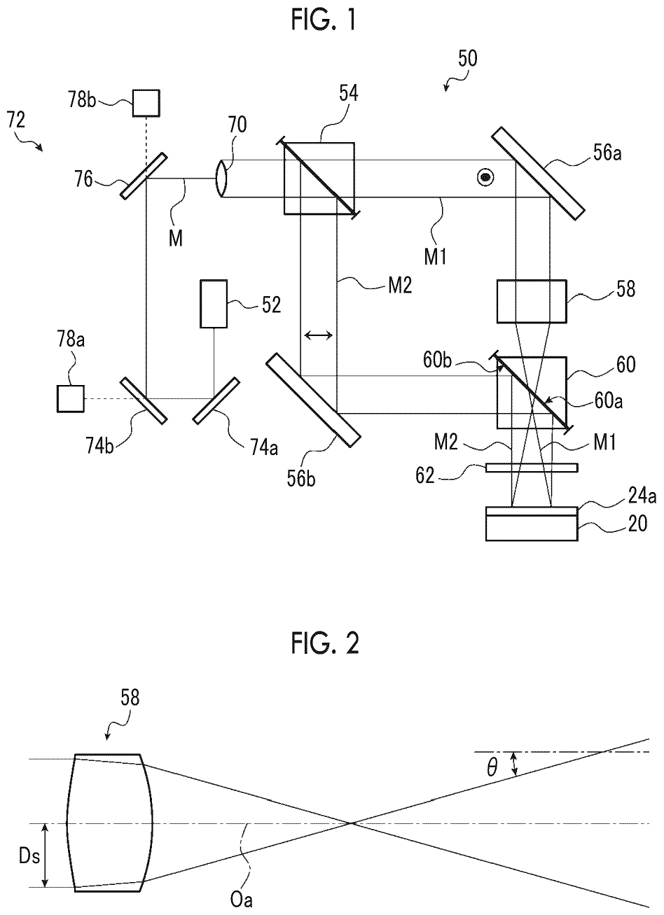

In addition, a focal length fL of the focusing element 58 according to the embodiment of the present invention is defined as follows. In the focusing element 58, as conceptually shown in FIG. 2, the distance from an optical axis Oa of the focusing element 58 in a direction orthogonal to the optical axis Oa is set as a distance Ds. In addition, a ray that is incident into a position at the distance Ds from the optical axis Oa of the focusing element 58 and is parallel to the optical axis Oa forms an angle with the optical axis Oa after transmitting through the focusing element 58, and this angle is set as θ. Further, “fL” represented by “fL=Ds/sin θ” is set as the focal length fL at the position at the distance Ds from the optical axis Oa in the focusing element 58.

Regarding the manufactured optical element (diffraction element), “fG” represented by “fG=Ds/tan θ” is set as a focal length fG at the position at the distance Ds from the optical axis Oa in the optical element. Specifically, the focal length fG of the optical element may be measured using a method described below.

The exposure system 50 in the example shown in the drawing exposes a non-exposed alignment film 24a including a compound having a photo-aligned group, for example, as an alignment film (photo-alignment film) for aligning a liquid crystal compound to form an alignment film having an alignment pattern. That is, the exposure system 50 shown in FIG. 1 implements the method of forming an alignment film according to the embodiment of the present invention.

In the following description, the non-exposed alignment film 24a including the compound having a photo-aligned group will also be referred to as “non-exposed alignment film 24a” for convenience of description. In the example shown in the drawing, the non-exposed alignment film 24a (alignment film 24 described below) is supported by a substrate 20.

The exposure system 50 according to the embodiment of the present invention is not limited to exposing the non-exposed alignment film 24a as in the example shown in the drawing.

That is, the exposure system 50 according to the embodiment of the present invention can be used for exposing various well-known materials such as a material having photosensitivity (photosensitive material).

In the exposure system 50, the light beam M having coherence emitted from the light source 52 is expanded by the beam expander element 70, the expanded light beam is split into linearly polarized light components orthogonal to each other by the beam splitter element 54, one of the linearly polarized light components is focused by the focusing element 58, the two linearly polarized light components are combined by the beam combiner element 60, and the combined light is converted into circularly polarized light by the polarization conversion element 62.

In the exposure system 50, by causing two circularly polarized light components having opposite turning directions to interfere with each other and to be incident into the non-exposed alignment film 24a, an interference fringe is formed, and the non-exposed alignment film 24a is exposed to the interference fringe to form an alignment pattern corresponding to the interference pattern on the non-exposed alignment film 24a.

Before being incident into the beam expander element 70, the light beam M emitted from the light source 52 is adjusted by the optical path adjustment optical system 72 such that the optical path is appropriate.

The optical path adjustment optical system 72 will be described below.

In addition, as described above, in the exposure system 50 according to the embodiment of the present invention, both of the beam expander element 70 and the optical path adjustment optical system 72 are provided as a preferable aspect. Accordingly, in the exposure system according to the embodiment of the present invention, either or both of the beam expander element 70 and the optical path adjustment optical system 72 do not need to be provided.

That is, in the exposure system according to the embodiment of the present invention, the light beam M emitted from the light source 52 may be directly incident into the beam expander element 70. Alternatively, the light beam M emitted from the light source 52 may be incident from the optical path adjustment optical system 72 into the beam splitter element 54. Alternatively, the light beam M emitted from the light source 52 may be directly incident into the beam splitter element 54.

In the exposure system 50, as the light source 52, a well-known light source can be used as long as it can emit collimated light (parallel light) having coherence.

In particular, as the light source having coherence, a laser light source that emits collimated light or a combination of a laser light source that emits diffused light and a collimating lens is suitably used.

In the exposure system 50 according to the embodiment of the present invention, a wavelength of the light beam M emitted from the light source 52 is not particularly limited. Accordingly, the light beam M emitted from the light source 52 may be ultraviolet light, visible light, or infrared light. In a case where the light beam M is visible light, the light beam M may be monochromatic light, may be mixed light of two or more color light components such as red light and blue light, or may be white light.

Here, the exposure system according to the embodiment of the present invention is suitably used for exposing the coating film (non-exposed alignment film 24a) as the photo-alignment film including the compound having a photo-aligned group. In consideration of this point, the light beam M emitted from the light source 52 is preferably ultraviolet light and more preferably light having a wavelength of 320 to 410 nm.

The light beam M having coherence emitted from the light source 52 is incident into the beam splitter element 54 through the optical path adjustment optical system 72.

The beam splitter element 54 splits the light beam M into a first light beam M1 and a second light beam M2 as linearly polarized light components orthogonal to each other. In the example shown in the drawing, for example, the first light beam M1 is S-polarized light, and the second light beam M2 is P-polarized light.

For example, the beam splitter element 54 splits the incident light beam M having coherence into the first light beam M1 as S-polarized light and the second light beam M2 as P-polarized light. The first light beam M1 is the first light in the present invention, and the second light beam M2 is the second light in the present invention.

In the present invention, the expressions such as “first” and “second” attached to light, a member, and the like are expressions for convenience of description to simply distinguish between two (a plurality of) things, and do not have technical meanings.

As the beam splitter element 54, various well-known polarization beam splitters such as a cube type or a plate type can be used as long as they can split the light beam M having coherence into linearly polarized light components orthogonal to each other.

In addition, as the beam splitter element 54, a combination of an optical element such as a half mirror or a non-polarization beam splitter that splits the light beam M having coherence and at least one polarizer can also be used. Light components split by the half mirror, the non-polarization beam splitter, or the like are not linearly polarized light components orthogonal to each other. However, by using the half mirror, the non-polarization beam splitter, or the like in combination with the polarizer, linearly polarized light components orthogonal to each other can be obtained. Here, the polarizer is not particularly limited, and various well-known polarizers, for example, a reflective polarizer such as a wire grid polarizer, an absorptive polarizer having dichroism, or a polarization prism such as a Glan-Thompson prism can be suitably used.

In the exposure system 50 in the example shown in the drawing, as a preferable aspect, a beam expander element for expanding the light beam M is provided between the light source 52 and the beam splitter element 54.

The exposure system 50 includes the beam expander element such that the area of an exposed region in the non-exposed alignment film 24a increases, and this configuration can also suitably deal with manufacturing of a large optical element (liquid crystal diffractive lens) or the like.

The beam expander element is not limited, and various beam expanders such as a Keplerian beam expander or a Galilean beam expander can be used as long as they can expand the light beam M that is linearly polarized light and has coherence.

In the exposure system according to the embodiment of the present invention, the position of the beam expander element 70 is not limited to a position between the light source 52 and the beam splitter element 54.

For example, the beam expander element 70 may be disposed on the optical paths of the first light beam M1 and the second light beam M2 between the beam splitter element 54 and the beam combiner element 60. Note that, in this case, the beam expander element 70 is disposed upstream of the focusing element 58. This point is also applicable to a case where the focusing element is provided on the optical path of the second light beam M2.

In addition, in the exposure system according to the embodiment of the present invention, a plurality of the beam expander elements 70 may be disposed on one optical path. For example, the beam expander element 70 may be disposed upstream and downstream of the beam splitter element 54.

Unless specified otherwise, in the present invention, the upstream side and the downstream side refer to an upstream side and a downstream side in a traveling direction of the light beam M from the light source 52 to the non-exposed alignment film 24a.

The first light beam M1 is reflected from the mirror 56a, is focused by the focusing element 58, and is incident into the beam combiner element 60. Accordingly, light transmitted through the focusing element 58 is focused such that the diameter expands in and after the focal point.

In the present invention, the focusing element 58 is the focal point-variable focusing element in the present invention. That is, the focusing element 58 has a focal length that continuously changes in a plane, that is, in the direction orthogonal to the optical axis. Further, in the focusing element 58, in a case where a maximum value of the focal length fL is represented by fLmax and a minimum value thereof is represented by fLmin, a ratio “fLmax/fLmin” of the maximum value fLmax to the minimum value fLmin of the focal length fL is more than 1.1. This point will be described below.

Although described below, in the exposure system according to the embodiment of the present invention that causes circularly polarized light components having opposite turning directions to interfere with each other and to expose the non-exposed alignment film 24a to the interference light, the non-exposed alignment film 24a is exposed using the focusing element 58 (focal point-variable focusing element). With the exposure system according to the embodiment of the present invention, an alignment film (photo-alignment film) that can manufacture the optical element (liquid crystal diffractive lens) according to the embodiment of the present invention including regions where the focal length (focal length fG) continuously changes in a plane, that is, in the direction orthogonal to the optical axis can be formed.

The focusing element 58 will be described below.

In addition, in the following description, in the focusing element 58 and various lenses, the direction orthogonal to the optical axis will be referred to as “in a plane) for convenience of description.

On the other hand, the second light beam M2 is reflected from the mirror 56b and is incident into the beam combiner element 60.

The beam combiner element 60 includes: a beam combiner element that includes a first surface 60a through which at least a part of incidence light transmits; and a second surface 60b from which at least a part of the incidence light is reflected. The light incident into and transmitted through the first surface 60a of the beam combiner element 60 and the light incident into and reflected from the second surface 60b of the beam combiner element 60 are combined and emitted from the beam combiner element 60.

In the following description, in order to simplify the sentences, “at least a part” in the description “at least a part of incidence light transmits”, “at least a part of the incidence light is reflected”, and the like is omitted.

In the exposure system 50 in the example shown in the drawing, the first light beam M1 that transmits through the focusing element 58 and is focused is incident into and transmits through the first surface 60a of the beam combiner element 60, and the second light beam M2 that is parallel light (collimated light) is incident into and reflected from the second surface 60b.

The first light beam M1 incident into and transmitted through the first surface 60a and the second light beam M2 incident into and reflected from the second surface 60b are combined as shown in FIG. 1. As described above, the first light beam M1 and the second light beam M2 are originally split from the same light beam M having coherence. Accordingly, the first light beam M1 and the second light beam M2 that are combined interfere with each other.

The beam combiner element 60 is not limited, and any well-known elements can be used as long as they include the first surface 60a through which incidence light transmits and the second surface 60b from which the incidence light is reflected and can combine the light incident into and transmitted through the first surface 60a and the light reflected from the second surface 60b.

As the beam combiner element 60, for example, a well-known beam splitter such as a cube type or a plate type, a half mirror, and the like can be used.

The beam combiner element 60 may be a polarization beam splitter or may be a non-polarization beam splitter. It is preferable that the beam combiner element 60 has properties of allowing the transmission of the first light beam M1 without converting the polarization state and allowing the reflection of the second light beam M2 without converting the polarization state.

Next, the first light beam M1 and the second light beam M2 that are combined by the beam combiner element 60 are converted into circularly polarized light components by the polarization conversion element 62.

As described above, the first light beam M1 and the second light beam M2 are linearly polarized light components orthogonal to each other. Accordingly, by the polarization conversion element 62, for example, the first light beam M1 is converted into right circularly polarized light, and the second light beam M2 is converted into left circularly polarized light. Alternatively, by the polarization conversion element 62, for example, the first light beam M1 is converted into left circularly polarized light, and the second light beam M2 is converted into right circularly polarized light.

Preferable examples of the polarization conversion element 62 include a so-called ¼ wave plate (¼ retardation plate, λ/4 plate) that has an in-plane retardation (retardation Re) of about ¼ wavelength at the wavelength of the incidence light, that is, the first light beam M1 and the second light beam M2.

As the ¼ wave plate, for example, a ¼ wave plate where a ratio between the retardation and the wavelength is 0.24 to 0.26 in the plane direction is preferable, and a ¼ wave plate where the ratio is 0.245 to 0.255 is more preferable.

The polarization conversion element 62 may be used in combination with a plurality of optical elements. In this case, a retardation obtained by adding up retardations of a plurality of optical elements forming the polarization conversion element 62 may be about ¼ wavelength.

A material for forming the polarization conversion element 62 used in the present invention is not particularly limited.

Accordingly, the polarization conversion element 62 may be, for example, a layer formed of a composition including a liquid crystal compound, or may be a layer formed of a polymer film (a film formed of a polymer (resin), in particular, a stretched polymer film).

Examples of the polymer film include a polycarbonate film, a cycloolefin polymer film, a TAC film, and a polyimide film.

The cycloolefin polymer film is more preferable from the viewpoint of obtaining excellent light fastness and withstanding long-term use.

In a case where the polarization conversion element 62 used in the present invention is a laminated wave plate consisting of a plurality of layers, the layers in the laminated wave plate may be formed of independently different materials.

It is preferable that the polarization conversion element 62 used in the present invention is a layer that is formed of a composition including a liquid crystal compound. By forming the polarization conversion element 62 using the composition including a liquid crystal compound, the thickness of the polarization conversion element can be reduced, and optical characteristics can be easily adjusted.

The composition including a liquid crystal compound is preferably a composition including a polymerizable liquid crystal compound. The layer formed of the composition including a polymerizable liquid crystal compound is preferably a layer formed by immobilizing the polymerizable liquid crystal compound by polymerization or the like.

The type of the liquid crystal compound is not particularly limited.

The liquid crystal compound can be classified into a rod-like liquid crystal compound and a disk-like liquid crystal compound (discotic liquid crystal compound) by the shape thereof. Further, each of the liquid crystal compounds can also be classified into a low molecular weight type and a polymer type. In general, the polymer refers to a compound having a polymerization degree of 100 or higher (Polymer Physics-Phase Transition Dynamics, Masao Doi, page 2, Iwanami Shoten Publishers, 1992). In the present invention, any liquid crystal compound can also be used.

In the liquid crystal composition, two or more rod-like liquid crystal compounds, two or more disk-like liquid crystal compounds, or a mixture of a rod-like liquid crystal compound and a disk-like liquid crystal compound may be used.

Further, as the rod-like liquid crystal compound, for example, liquid crystal compounds described in claim 1 of JP1999-513019A (JP-H11-513019A) and paragraphs “0026” to “0098” of JP2005-289980A can be preferably used. On the other hand, as the disk-like liquid crystal, for example, liquid crystals described in paragraphs “0020” to “0067” of JP2007-108732A and paragraphs “0013” to “0108” of JP2010-244038A can be preferably used.

In the exposure system according to the embodiment of the present invention, the position of the polarization conversion element 62 is not limited to a position downstream of the beam combiner element 60 in the example shown in the drawing.

For example, instead of being disposed downstream of the beam combiner element 60, the polarization conversion elements 62 may be disposed on the optical path of the first light beam M1 from the beam splitter element 54 to the beam combiner element 60 and on the optical path of the second light beam M2 from the beam splitter element 54 to the beam combiner element 60, respectively.

In a case where the polarization conversion element 62 is disposed upstream of the beam combiner element 60, circularly polarized light components having the same turning direction may be incident into the first surface 60a and the second surface 60b of the beam combiner element 60.

Examples of a method of converting circularly polarized light components incident into the first surface 60a and the second surface 60b of the beam combiner element 60 into circularly polarized light components having the same turning direction include a method of setting slow axes of the polarization conversion elements 62 disposed on the optical path of the first light beam M1 and on the optical path of the second light beam M2 such that linearly polarized light components orthogonal to each other are converted into circularly polarized light components having the same turning direction. In addition, a method can also be used in which linearly polarized light components orthogonal to each other are converted into right circularly polarized light and left circularly polarized light by the polarization conversion elements 62 disposed on the optical path of the first light beam M1 and on the optical path of the second light beam M2, and a ½ wave plate is disposed on one of the optical paths to convert the circularly polarized light into circularly polarized light having the same turning direction as that of the other optical path such that the circularly polarized light components incident into the first surface 60a and the second surface 60b of the beam combiner element 60 are converted into circularly polarized light components having the same turning direction.

As described above, in the exposure system 50, by causing two circularly polarized light components having opposite turning directions to interfere with each other and to be incident into the non-exposed alignment film 24a, an interference fringe is formed, and the non-exposed alignment film 24a is exposed to form an interference pattern, that is, an alignment pattern on the non-exposed alignment film 24a.

In the exposure system 50, the alignment pattern formed on the non-exposed alignment film 24a is changed by the focusing element 58. In other words, by selecting the focusing element 58 to be used, the alignment pattern to be formed on the non-exposed alignment film 24a can be selected.

Here, in the exposure system 50 according to the embodiment of the present invention, the focusing element 58 as the focal point-variable focusing element where the focal length continuously changes in a plane, that is, in the direction orthogonal to the optical axis is used. That is, in the focusing element 58, the focal length continuously changes in a plane, that is, in a direction away from the optical axis.

As shown in FIG. 1, in the exposure system that forms the concentric alignment pattern (interference pattern) by the exposure using interference light, typically, a positive lens is used as the focusing element. In the positive lens used in the exposure system, typically, the focal length is constant in a plane, that is, in the direction orthogonal to the optical axis.

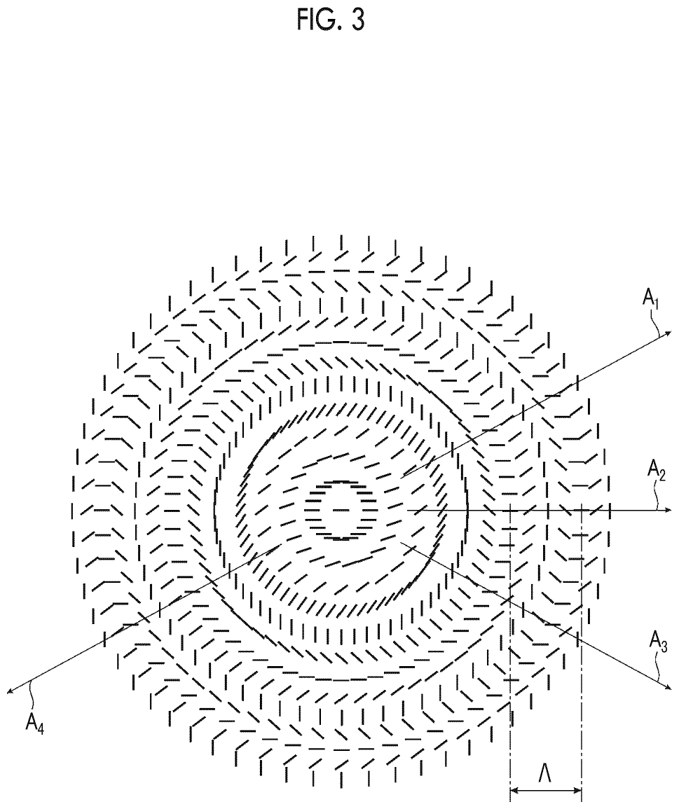

In the same exposure system as the exposure system 50, in a case where the focusing element is a positive lens, as conceptually shown in FIG. 3, the alignment pattern that is formed on the non-exposed alignment film 24a by the exposure system includes a pattern where a short straight line changes while continuously rotating in one direction in a radial shape as indicated by an arrow in the drawing.

In other words, in a case where the focusing element 58 is a positive lens, the alignment pattern that is formed on the non-exposed alignment film 24a by the exposure system 50 is a concentric alignment pattern that includes one direction in which a short straight line changes while continuously rotating in a concentric shape from the inner side toward the outer side as shown in FIG. 3. That is, this alignment pattern is a pattern including circles formed by short straight lines having the same orientation in a concentric shape.

In the exposure system 50, due to the interference between right circularly polarized light and left circularly polarized light, the polarization state of light to be irradiated on the non-exposed alignment film 24a periodically changes according to the interference fringe.

Here, as shown in FIG. 1, the first light beam M1 is focused by the focusing element (positive lens) and is diffused in and after the focal point. Accordingly, an intersection state between the right circularly polarized light and the left circularly polarized light changes from the inner side to the outer side of the concentric circle. As a result, an alignment pattern where the period decreases from the inner side toward the outer side is obtained.

Specifically, in the alignment pattern, a short straight line changes while continuously rotating in a plurality of directions from the center toward the outer side, for example, a direction indicated by an arrow A₁, a direction indicated by an arrow A₂, a direction indicated by an arrow A₃, a direction indicated by an arrow A₄, or . . . . In the following description, the short straight line of which the orientation changes while continuously rotating will be referred to as “short line” for convenience of description.

The rotation direction of the short line is the same direction in all of the directions (one direction). In the example shown in the drawing, in all the directions including the direction indicated by the arrow A₁, the direction indicated by the arrow A₂, the direction indicated by the arrow A₃, and the direction indicated by the arrow A₄, the rotation direction of the short line is counterclockwise.

That is, in a case where the arrow A₁ and the arrow A₄ are assumed as one straight line, the rotation direction of the short line is reversed at the center on the straight line. For example, the straight line formed by the arrow A₁ and the arrow A₄ is directed in the right direction (arrow A₁ direction) in the drawing. In this case, the short line initially rotates clockwise from the outer side toward the center, the rotation direction is reversed at the center, and then the short line rotates counterclockwise from the center toward the outer side.

In addition, in the interference pattern, in a case where a length over which the orientation of the short line rotates by 180° in the one direction in which the direction of the short line changes while continuously rotating is set as a single period Λ, the length of the single period Λ gradually decreases from the inner side toward the outer side.

In the exposure system 50 shown in FIG. 1, in a case where a positive lens where the focal length is constant in a plane is used as the focusing element, a decrease in single period Λ from the inner side toward the outer side is an inverse-proportional monotonic decrease.

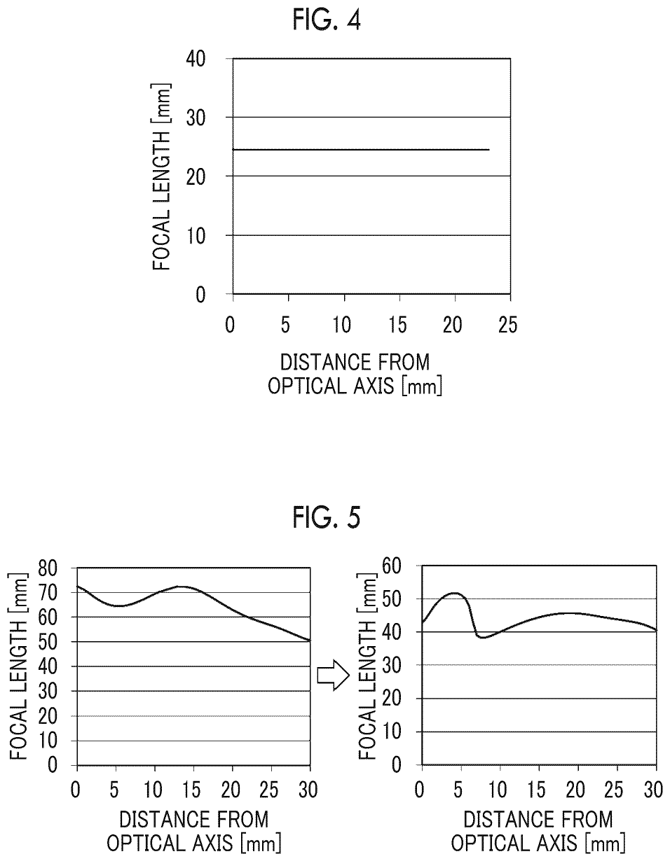

In a case where an optical element (liquid crystal diffractive lens) is manufactured using an alignment film having the above-described alignment pattern, the obtained optical element acts as a condenser lens where the focal length is constant in a plane as conceptually shown in FIG. 4 as in the positive lens. In FIG. 4, the horizontal axis represents the distance from the optical axis, that is, the center, and the vertical axis represents the focal length.

As the single period A decreases, the diffraction in the optical element increases, and thus the focal length decreases as described above.

On the other hand, in the exposure system 50 according to the embodiment of the present invention that forms the concentric alignment pattern (interference pattern) by performing the exposure using interference light, the focusing element 58 where the focal length continuously changes in a plane, that is, in the direction orthogonal to the optical axis is used.

In the exposure system 50 according to the embodiment of the present invention, with the above-described configuration, the degree of the decrease in single period A in the concentric alignment pattern can increase or vary instead of the inverse-proportional monotonic decrease. In the present invention, a region where the length of the single period A in the alignment pattern increases may be included or may not be included.

Therefore, by manufacturing an optical element using an alignment film having the above-described alignment pattern, an optical element including regions where the focal length continuously changes in a plane, that is, in the direction orthogonal to the optical axis can be obtained. Specifically, this optical element includes regions where the focal length continuously changes in a direction from the center toward the outer side of the concentric circle in the alignment pattern.

For example, in a case where the non-exposed alignment film 24a is exposed using the focusing element 58 having a focal length profile conceptually shown on the left side of FIG. 5 described below in Examples, an optical element having a focal length profile that includes regions where the focal length continuously changes in the direction away from the optical axis in a plane as conceptually shown on the right side of FIG. 5 described below in Examples can be manufactured.

Specifically, the focal length profile refers to a change in focal length corresponding to the distance from the optical axis in a plane of the optical element such as a lens. Accordingly as described above, In FIG. 5, the horizontal axis represents the distance from the optical axis, and the vertical axis represents the focal length. Accordingly, the above-described general optical element where the focal length is constant in a plane has a focal length profile that is a horizontal straight line as shown above in FIG. 4.

The focal length profile of the focusing element 58 shown on the left of FIG. 5 is calculated using “fL=Ds/sin θ” described above, and the focal length profile of the manufactured optical element (diffraction element) shown on the right of FIG. 5 is calculated using “fG=Ds/tan θ” described above.

That is, with the exposure system according to the embodiment of the present invention, for example, during the manufacturing of an optical element, an alignment film for obtaining an optical element that includes regions where the focal length continuously changes without including a boundary region or the like can be simply formed with high productivity.

In the exposure system 50 according to the embodiment of the present invention, the focusing element 58 has a focal length that continuously changes in a plane, that is, in the direction orthogonal to the optical axis.

Here, the focal length profile of the focusing element 58 is not particularly limited.

The focal length profile of the alignment pattern (interference pattern) of the alignment film that is formed by the exposure system 50, that is, the optical element is basically determined depending on the focal length profile of the focusing element 58. Accordingly, regarding the focal length profile of the focusing element 58, depending on a focal length profile of a desired optical element, a profile for obtaining the optical element having the focal length profile may be appropriately set by a design, a simulation, or the like.

Here, in the focusing element 58, it is preferable that the focal length profile has one or more extreme values. The extreme values in the focal length profile are a point (maximum value) where the focal length shifts from a decrease to an increase and a point (minimum value) where the focal length shifts from an increase to a decrease.

With the configuration in which the focal length profile of the focusing element 58 has one or more extreme values, an alignment pattern capable of manufacturing an optical element where a change in focal length profile is complex can be formed.

The number of the extreme values in the focal length profile of the focusing element 58 is more preferably 2 or more.

Further, the focusing element 58 is the focal point-variable focusing element having the focal length profile where the focal length continuously changes, and in a case where the maximum value of the focal length fL is represented by fLmax and the minimum value thereof is represented by fLmin, the ratio “fLmax/fLmin” of the maximum value fLmax to the minimum value fLmin is more than 1.1.

Specifically, in a case where the focusing element 58 is a lens (optical lens), the focusing element 58 is a focusing element described below.

In the focusing element 58, as conceptually shown in FIG. 2, the distance from the optical axis Oa of the focusing element 58 in the direction orthogonal to the optical axis Oa is set as the distance Ds. In addition, a ray that is incident into a position at the distance Ds from the optical axis Oa of the focusing element 58 and is parallel to the optical axis Oa forms an angle with the optical axis Oa after transmitting through the focusing element 58, and this angle is set as θ. Further, “fL” represented by “fL=Ds/sin θ” is set as the focal length fL at the position at the distance Ds from the optical axis Oa in the focusing element 58.

In the present invention, in a case where the focusing element 58 is a lens, the lens is the focal point-variable focusing element where the focal length fL defined as described above continuously changes in the direction orthogonal to the optical axis Oa. In addition, in the focusing element 58, in a case where the maximum value of the focal length fL defined as described above is represented by fLmax and the minimum value thereof is represented by fLmin, the ratio “fLmax/fLmin” of the maximum value fLmax to the minimum value fLmin is more than 1.1.

In a case where the ratio “fLmax/fLmin” is less than 1.1, there is an inconvenience in that, for example, an alignment film corresponding to an optical element having a sufficient change in focal length profile cannot be formed.

From the viewpoint that, for example, an alignment film corresponding to an optical element having a sufficient change in focal length profile can be suitably formed, the ratio “fLmax/fLmin” is preferably 1.2 or more and more preferably 1.3 or more.

The upper limit of the ratio “fLmax/fLmin” is not limited and is preferably 200 or less and more preferably 100 or less in consideration of the design, the manufacturing of the focusing element, the difficulty of the manufacturing of the optical element, and the like.

In the exposure system according to the embodiment of the present invention, the focusing element 58 is not limited, and various optical elements can be used as long as they satisfy the above-described conditions.

Here, it is preferable that the focusing element 58 includes a plurality of lenses. In addition, it is preferable that the focusing element 58 includes at least one of an aspherical lens or a cylinder lens (cylindrical lens).

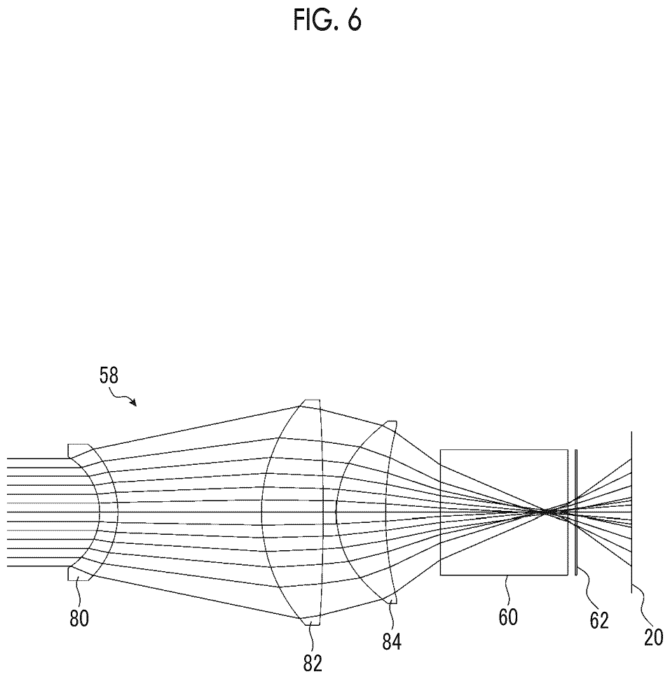

For example, as conceptually shown in FIG. 6, a negative meniscus lens 80, both positive lenses 82 having different curvatures, and a positive meniscus lens 84 having an aspherical surface are combined to form the focusing element 58.

In addition, in the present invention, in a method in which a cylinder lens is used as the focusing element 58 or a method in which the focusing element 58 includes a cylinder lens, a method capable of obtaining a non-axisymmetric focal length profile in the focusing element 58 can also be used. In addition, in the present invention, a method of obtaining the non-axisymmetric focal length profile of the focusing element 58 by disposing the optical axis of the positive lens to be tilted with respect to the traveling direction of the first light beam M1 can also be used.

Further, in the present invention, a method of obtaining the non-axisymmetric focal length profile of the focusing element 58 by disposing the surface (exposure surface) of the non-exposed alignment film 24a to be tilted with respect to the optical axis of the positive lens as the focusing element can also be used.

In addition, a method of obtaining the non-axisymmetric focal length profile of the focusing element 58 by causing the second light beam M2 to be incident such that the traveling direction of the second light beam M2 is tilted with respect to the incident surface of the beam combiner element 60 can also be used.

Two or more of the above-described methods may be used in combination.

The non-exposed alignment film 24a may be disposed downstream or upstream of the focal point of the focusing element 58.

By disposing the object to be irradiated downstream of the focal point of the focusing element 58, a space where the beam combiner element 60, the polarization conversion element 62, and the like are disposed can be secured between the focusing element 58 and the object to be irradiated. In addition, by disposing the object to be irradiated upstream of the focal point of the focusing element 58, the exposure system 50 can be minimized.

In the exposure system 50 in the example shown in the drawing, the focusing element 58 is disposed on only the optical path of the first light beam M1 that transmits through the first surface 60a of the beam combiner element 60. However, the present invention is not limited to this example.

That is, the focusing element 58 may be disposed on only the optical path of the second light beam M2 that is reflected from the second surface 60b of the beam combiner element 60, or may be disposed on both of the optical path of the first light beam M1 and the optical path of the second light beam M2. Note that, in a case where the focusing element 58 is disposed on both of the optical path of the first light beam M1 and the optical path of the second light beam M2, the focusing element 58 disposed on the optical path of the first light beam M1 is different from that disposed the optical path of the second light beam M2.

In this case, for example, an alignment pattern is formed by interference of two spherical waves, and thus the degree of freedom of the alignment pattern can be improved.

In addition, in a case where the focusing element is disposed on both of the optical path of the first light beam M1 and the optical path of the second light beam M2, one of the focusing elements may be the focusing element 58, that is, the focal point-variable focusing element according to the embodiment of the present invention, and the other one of the focusing elements may be a typical positive lens where the focal length does not change in a plane.

In addition, the disposition position of the focusing element 58 is not limited to the upstream of the beam combiner element 60, and various positions can be used. In this case, a plurality of the focusing elements 58 may be disposed.

For example, in a state where the focusing element 58 is disposed on at least one of the optical path of the first light beam M1 or the optical path of the second light beam M2, the focusing element 58 may be further disposed between the beam combiner element 60 and the polarization conversion element 62.

Incidentally, the first light beam M1 is focused by the focusing element 58 and is diffused in and after the focal point. That is, a part of the first light beam M1 emitted from the beam combiner element 60 has an angle with respect to the optical axis.

As the angle between the first light beam M1 and the optical axis increases, the alignment pattern (interference pattern) formed on the non-exposed alignment film 24a is finer. Specifically, in a case where a direction perpendicular to a main surface of the non-exposed alignment film 24a, that is, the normal direction is set to 0°, as the angle at which the first light beam M1 is incident into the non-exposed alignment film 24a increases, a fine interference pattern can be obtained. That is, as the angle at which the first light beam M1 is incident into the non-exposed alignment film 24a is wider, a fine interference pattern is formed on the non-exposed alignment film 24a.

Specifically, as shown in FIG. 3, in the pattern where the short line changes while continuously rotating in the one direction, as the angle at which the first light beam M1 is incident into the non-exposed alignment film 24a is wider, the length of the single period A over which the short line rotates by 180° in the one direction (the direction of the arrow) decreases.

The main surface is the maximum surface of a sheet-shaped material (a film, a layer, or a plate-shaped material).

In the exposure system 50 according to the embodiment of the present invention, an angle at which light transmits through the focusing element 58 and is emitted from the beam combiner element 60 with respect to the optical axis of the light is not limited.

Here, it is preferable that, in a case where parallel light as the light transmitted through the focusing element 58 (in the example shown in the drawing, the first light beam M1) is incident into the light control element 58, at least a part of the light emitted from the beam combiner element 60 has an angle of 15° or more with respect to an optical axis.

The maximum value of the angle of the light emitted from the beam combiner element 60 with respect to the optical axis is more preferably 17° or more and still more preferably 20° or more.

With the configuration in which at least a part of the light emitted from the beam combiner element 60 has an angle of 15° or more with respect to the optical axis, a fine interference pattern can be formed. In particular, in a case where the light (in the example shown in the drawing, the second light beam M2) that cannot transmit through the focusing element 58 is parallel light, a fine interference pattern can be suitably formed.

In the exposure system 50 according to the embodiment of the present invention, the intensity of light with which the non-exposed alignment film 24a is irradiated is preferably uniform in a plane of the non-exposed alignment film 24a.

Specifically, in the exposure system 50 according to the embodiment of the present invention, a ratio maximum value/minimum value of the intensity of light in a plane (the direction orthogonal to the optical axis) on an exposure surface of an exposed medium is preferably 25 times or less. In the example shown in the drawing, on the surface of the non-exposed alignment film 24a, the ratio maximum value/minimum value of the intensity of light is preferably 25 times or less.

In this case, the intensity of light refers to an illuminance.

The above-described configuration is preferable from the viewpoint that, for example, the exposure accuracy of the non-exposed alignment film 24a can be improved.

The ratio maximum value/minimum value of the intensity of light in the exposure surface of the exposed medium is more preferably 10 times or less, still more preferably 5 times or less, and most preferably 1 time, that is, uniform over the entire surface.

In the exposure system 50 according to the embodiment of the present invention, the length of the optical path length from the light source 52 to the non-exposed alignment film 24a is not limited, and the optical path length between the beam splitter element 54 and the beam combiner element 60 is preferably 800 mm or less.

The above-described configuration is preferable from the viewpoints that, for example, the size of the exposure system 50 can be reduced or a decrease in exposure accuracy caused by fluctuation of air, other vibrations, and the like can be suppressed.

The optical path length between the beam splitter element 54 and the beam combiner element 60 is more preferably 600 mm or less and still more preferably 400 mm or less.

The light reflected from the surface of the optical element forming the exposure system 50 is noise, and the exposure accuracy of the non-exposed alignment film 24a decreases.

In consideration of this point, preferably in at least one optical element in the optical member forming the exposure system 50, more preferably in more optical elements, still more preferably in all the optical elements downstream of the beam expander element 70 including the beam expander element 70, still more preferably in all the optical elements, a surface reflectivity of light having a wavelength emitted from the light source 52 is 0.5% or less.

In each of the optical elements, the surface where the surface reflectivity is 0.5% or less may be at least one surface and is preferably both of an incident surface and an emission surface of light.

As a result, a decrease in exposure accuracy caused by noise can be suppressed, and a higher-accuracy alignment pattern can be formed on the non-exposed alignment film 24a (alignment film 24).

The surface reflectivity of the optical member is more preferably 0.3% or less and still more preferably 0.2% or less.

A method of setting the surface reflectivity of the optical member to be 0.5% or less is not limited, and various well-known can be used.

For example, a method of providing an anti-reflection (AR) layer (AR film) on the surface or a method of providing a moth eye layer (moth eye film) on the surface can be used.

As described above, the exposure system 50 in the example shown in the drawing includes the optical path adjustment optical system 72 that is provided between the light source 52 and the beam expander element 70, detects the light beam M emitted from the light source 52 on the upstream of the beam expander element 70, and adjusts the optical path (optical axis) of the light beam M.

In the example shown in the drawing, the optical path adjustment optical system 72 includes the actuated mirrors 74a and 74b, the mirror 76, and the detectors 78a and 78b.

The actuated mirrors 74a and 74b are well-known angle-variable mirrors where the angle can be adjusted by an actuator such as a piezoelectric element.

The detector 78a is a detector that detects an incidence position of the light beam M into the actuated mirror 74a. The detector 78b is a detector that detects an incidence position of the light beam M into the mirror 76. As a method of detecting the light beam M using the detectors 78a and 78b, various well-known methods such as a method of detecting light transmitted through the actuated mirror 74a and the mirror 76 using a diode detector can be used.

The mirror 76 is a well-known reflecting mirror.

In the exposure system 50, during the exposure of the non-exposed alignment film 24a, the optical path adjustment optical system 72 detects the incidence position of the light beam M on the actuated mirror 74a using the detector 78a and detects the incidence position of the light beam M on the mirror 76 using the detector 78b.

Based on the detection results of the light beam M, the optical path adjustment optical system 72 adjusts the angles of the actuated mirrors 74a and 74b such that the optical path of the light beam M from the light source 52 to the beam expander element 70 is appropriate.

Not only in the exposure system 50 but also in various optical systems, the light source 52 varies over time such that the optical path of the light beam deviates.

As a result, the incidence position of interference light into the non-exposed alignment film 24a deviates such that the exposure position on the non-exposed alignment film 24a is different from a desired position. In addition, the deviation in the optical path of the light beam M is the deviation in the incidence position and the angle of the light beam M into each of the optical elements. In a case where the deviation of the incidence position and the incidence angle into the optical element occurs, each of the optical elements cannot exhibit predetermined optical performance, and the exposure accuracy of the non-exposed alignment film 24a decreases.

On the other hand, as a preferable aspect, the exposure system 50 shown in the drawing includes the optical path adjustment optical system 72 that adjusts the optical path of the light beam M. As a result, the non-exposed alignment film 24a can be exposed in a state where the optical path of the light beam M is at an appropriate position. As a result, in the exposure system 50, high-accuracy exposure can be performed at the desired position of the non-exposed alignment film 24a.

In the exposure system according to the embodiment of the present invention, the optical path adjustment optical system is not limited to the configuration in the example shown in the drawing, and various well-known automatic adjustment units that adjust an optical path of a light beam used in various optical systems (optical devices) can be used.

For example, a unit that detects an interference fringe formed by the interference light of the first light beam M1 and the second light beam M2 on the downstream side of the beam combiner element 60 instead of the upstream side of the beam splitter element 54 as in the example shown in the drawing to adjust the optical path of the first light beam M1 and/or the second light beam M2 such that an appropriate interference fringe can be obtained based on the detection result of the interference fringe can be used.

In the example shown in the drawing, a method of detecting an interference fringe on the downstream side of the polarization conversion element 62, adjusting the angle of the mirror 56a and/or the mirror 56b to obtain an appropriate interference fringe, and adjusting the optical path of the first light beam M1 and/or the second light beam M2 can be used.

In the adjustment unit of the light beam optical path, the interference fringe can be detected by disposing an imaging element such that an imaging surface is positioned on the exposure surface.

In addition, as the adjustment unit of the light beam optical path, only one adjustment unit may be used, or a plurality of adjustment units may be used in combination.

As described above, the non-exposed alignment film 24a is a coating film including a compound having a photo-aligned group. That is, the exposure system 50 shown in FIG. 1 implements the method of forming an alignment film according to the embodiment of the present invention, the method including exposing the coating film including the compound having a photo-aligned group using the exposure system according to the embodiment of the present invention.

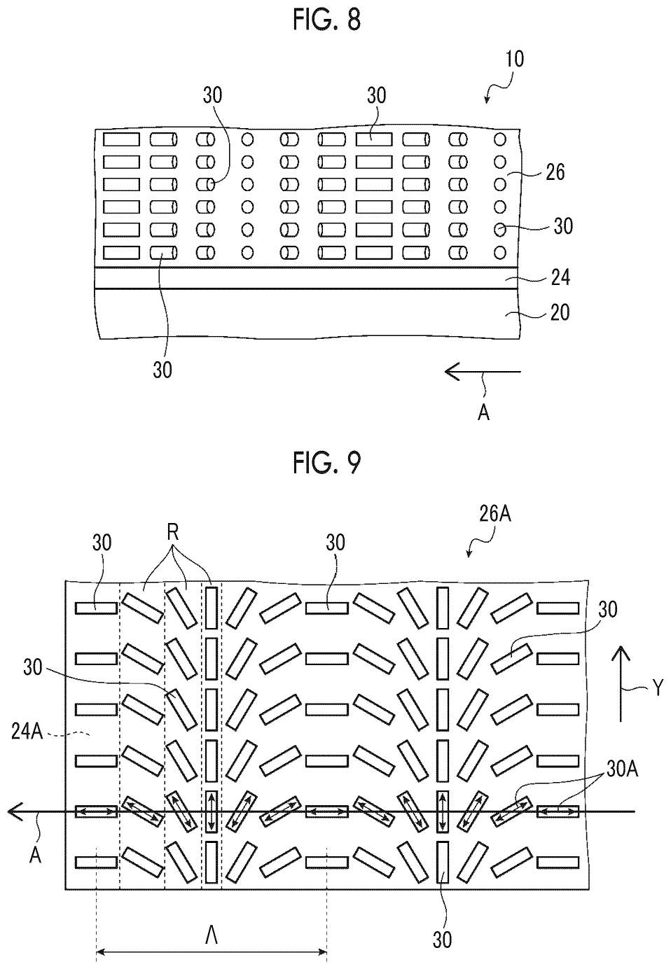

In addition, in the example shown in the drawing, the non-exposed alignment film 24a, that is, the alignment film 24 is supported by the substrate 20 (refer to FIG. 8). That is, in the method of forming an alignment film according to the embodiment of the present invention shown in FIG. 1, for example, the alignment film 24 formed of a photo-alignment film is formed by forming the non-exposed alignment film 24a on the substrate 20 to expose the non-exposed alignment film 24a using the exposure system 50 according to the embodiment of the present invention.

As the substrate 20, various sheet-shaped materials (films or plate-shaped materials) can be used as long as they can support the non-exposed alignment film 24a, that is, the alignment film 24 and an optically-anisotropic layer 26 described below.

As the substrate 20, a transparent support is preferable, and examples thereof include a polyacrylic resin film such as polymethyl methacrylate, a cellulose resin film such as cellulose triacetate, a cycloolefin polymer film (for example, trade name “ARTON”, manufactured by JSR Corporation; or trade name “ZEONOR”, manufactured by Zeon Corporation), polyethylene terephthalate (PET), polycarbonate, and polyvinyl chloride. The support is not limited to a flexible film and may be a non-flexible substrate such as a glass substrate.

A coating film including a compound having a photo-aligned group is formed on a surface of the substrate 20, and this coating film is dried to form the non-exposed alignment film 24a.

Next, the dried coating film is irradiated with interference light that is formed by the above-described exposure system 50 according to the embodiment of the present invention and where the first light beam M1 and the second light beam M2 of circularly polarized light are combined. As a result, the non-exposed alignment film 24a is exposed to the interference pattern, that is, the alignment pattern to form an alignment pattern, and the alignment film 24 having the concentric alignment pattern is formed.

As described above, in the alignment pattern, the degree of the decrease in the single period A in the direction from the center toward the outer side of the concentric circle increases or varies according to the focal length profile of the focusing element 58 instead of the inverse-proportional monotonic decrease.

Preferable examples of the compound having a photo-aligned group that is, the photo-alignment material used in the photo-alignment film that can be used in the present invention include: an azo compound described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B; an aromatic ester compound described in JP2002-229039A; a maleimide- and/or alkenyl-substituted nadiimide compound having a photo-alignable unit described in JP2002-265541A and JP2002-317013A; a photocrosslinking silane derivative described in JP4205195B and JP4205198B, a photocrosslinking polyimide, a photocrosslinking polyamide, or a photocrosslinking ester described in JP2003-520878A, JP2004-529220A, and JP4162850B; and a photodimerizable compound, in particular, a cinnamate (cinnamic acid) compound, a chalcone compound, or a coumarin compound described in JP1997-118717A (JP-H9-118717A), JP1998-506420A (JP-H10-506420A), JP2003-505561A, WO2010/150748A, JP2013-177561A, and JP2014-12823A.

Among these, an azo compound, a photocrosslinking polyimide, a photocrosslinking polyamide, a photocrosslinking ester, a cinnamate compound, or a chalcone compound is suitably used.

In the method of manufacturing an optical element according to the embodiment of the present invention, a composition including a liquid crystal compound is applied to the alignment film formed as described above and is dried, and the liquid crystal compound is optionally cured.

As a result, for example, the above-described optical element (liquid crystal diffractive lens) having the concentric liquid crystal alignment pattern can be manufactured.

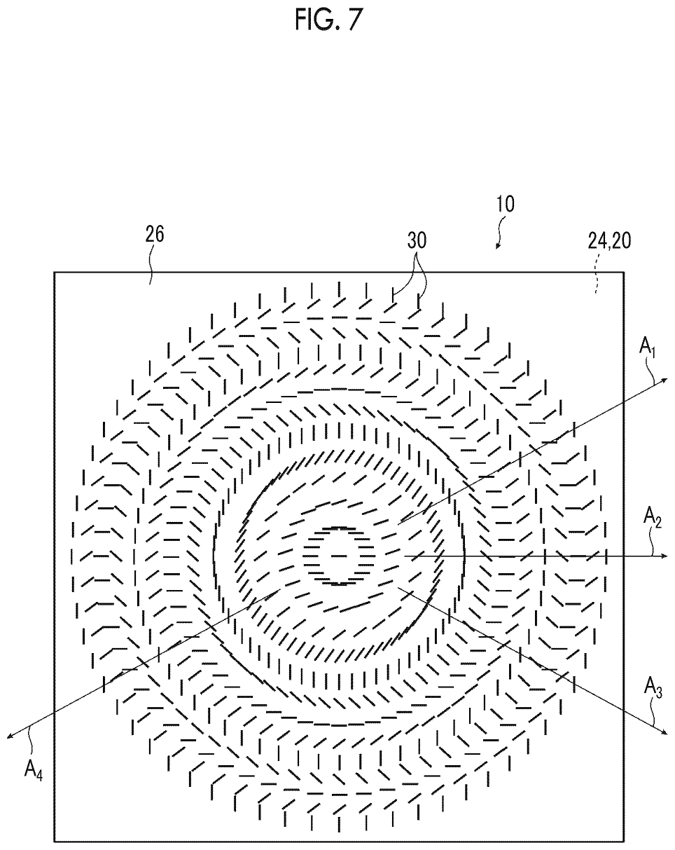

FIGS. 7 and 8 conceptually show an example of the optical element where the optically-anisotropic layer 26 is formed on the alignment film 24 having the alignment pattern shown in FIG. 3 by the exposure using a typical optical system where a positive lens is used as the focusing element.

FIG. 7 is a plan view conceptually showing the optical element, and FIG. 8 is a cross-sectional view conceptually showing the optical element. The plan view is a view in a case where the optical element is seen from a thickness direction (laminating direction of the respective layers (films)).

An optical element 10 shown in FIGS. 7 and 8 includes the optically-anisotropic layer 26 as a liquid crystal layer that is formed on the alignment film 24 using the composition including a liquid crystal compound.

As described above, as shown in FIG. 3, the alignment film 24 includes the concentric alignment pattern including the alignment pattern where the orientation of the short line changes while continuously rotating in one direction in a radial shape from the inner side toward the outer side.

The liquid crystal alignment pattern in the optically-anisotropic layer 26 follows the alignment pattern formed on the alignment film 24 (non-exposed alignment film 24a). Specifically, a liquid crystal compound 30 is aligned such that a longitudinal direction matches with a longitudinal direction of a single line in the alignment pattern of the alignment film 24.

Accordingly, the optically-anisotropic layer 26 that is formed on the alignment film 24 using the composition including a liquid crystal compound includes a liquid crystal alignment pattern where an orientation of an optical axis derived from a liquid crystal compound 30 changes while continuously rotating in one direction in a radial shape from the inner side toward the outer side. That is, the liquid crystal alignment pattern in the optically-anisotropic layer 26 shown in FIGS. 7 and 8 is a concentric pattern including the one direction in which the orientation of the optical axis derived from the liquid crystal compound 30 changes while continuously rotating in a concentric shape from the inner side toward the outer side.

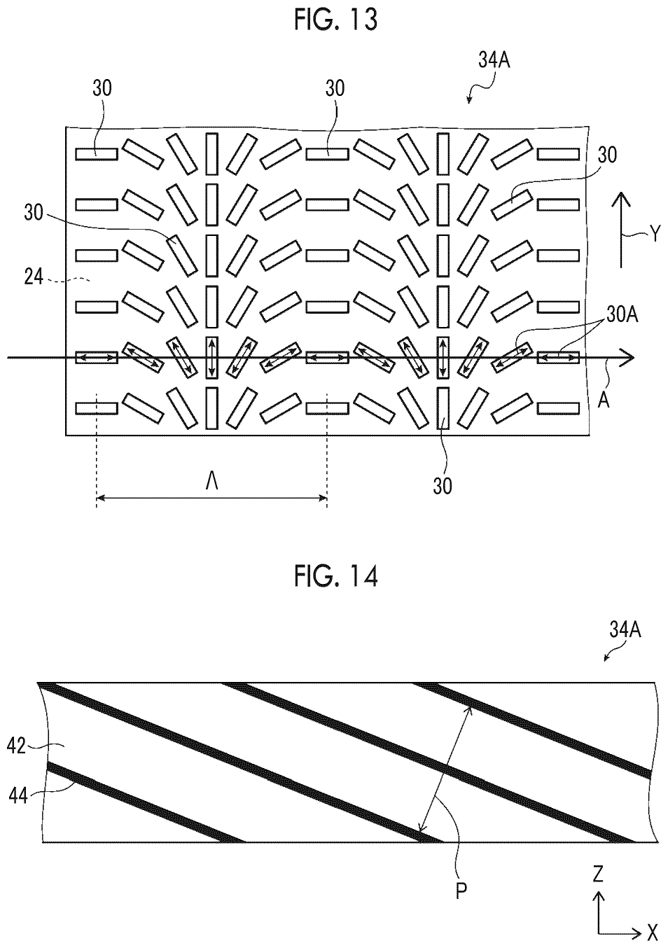

In FIGS. 7 to 15 (excluding FIG. 14), for example, a rod-like liquid crystal compound is used as the liquid crystal compound 30. Therefore, the direction of the optical axis matches with a longitudinal direction of the liquid crystal compound 30.

Specifically, in the optically-anisotropic layer 26, the orientation of the optical axis of the liquid crystal compound 30 changes while continuously rotating in a plurality of directions from the center toward the outer side of the optically-anisotropic layer 26, for example, a direction indicated by an arrow A₁, a direction indicated by an arrow A₂, a direction indicated by an arrow A₃, a direction indicated by an arrow A₄, or . . . .

Accordingly, in the optically-anisotropic layer 26, the rotation direction of the optical axis of the liquid crystal compound 30 is the same as all the directions (one direction). In the example shown in the drawing, in all the directions including the direction indicated by the arrow A₁, the direction indicated by the arrow A₂, the direction indicated by the arrow A₃, and the direction indicated by the arrow A₄, the rotation direction of the optical axis of the liquid crystal compound 30 is counterclockwise.

That is, in a case where the arrow A₁ and the arrow A₄ are assumed as one straight line, the rotation direction of the optical axis of the liquid crystal compound 30 is reversed at the center of the optically-anisotropic layer 26 on the straight line. For example, the straight line formed by the arrow A₁ and the arrow A₄ is directed in the right direction (arrow A₁ direction) in the drawing. In this case, the optical axis of the liquid crystal compound 30 initially rotates clockwise from the outer side to the center of the optically-anisotropic layer 26, the rotation direction is reversed at the center of the optically-anisotropic layer 26, and then the optical axis of the liquid crystal compound 30 rotates counterclockwise from the center to the outer side of the optically-anisotropic layer 26.

In addition, in the optically-anisotropic layer 26 of the optical element 10, in the liquid crystal alignment pattern, in a case where a length over which the orientation of the optical axis derived from the liquid crystal compound rotates by 180° in the one direction in which the orientation of the optical axis derived from the liquid crystal compound 30 changes while continuously rotating is set as a single period, the length of the single period gradually decreases from the inner side toward the outer side.

Here, in the alignment film 24 shown in FIG. 3, the alignment pattern that is formed by the exposure system where a typical positive lens is used as the focusing element, and the length of the single period A monotonically decreases inverse-proportionally from the inner side toward the outer side.

On the other hand, in the exposure system 50 according to the embodiment of the present invention, the focusing element 58 (focal point-variable focusing element) having a focal length that continuously changes in the direction orthogonal to the optical axis is used. Therefore, in the alignment film 24 where the alignment pattern is formed by the exposure using the exposure system 50 according to the embodiment of the present invention, the degree of the decrease in the single period A in the concentric alignment pattern increases or varies instead of the inverse-proportional monotonic decrease.

Accordingly, although not shown in FIG. 7, the length of the single period in the optically-anisotropic layer 26 where the alignment film 24 is formed increases or varies instead of the monotonic decrease from the inner side toward the outer side. In the present invention, a region where the length of the single period A in the liquid crystal alignment pattern increases may be included or may not be included.

For example, in the above-described optical element having the focal length profile shown on the right side of FIG. 5, the degree of the decrease in the length of the single period varies from the inner side toward the outer side according to the focal length profile, and the region where the length of the single period increases is included.

However, regarding the optical action and the like of the optically-anisotropic layer described below, the optically-anisotropic layer 26 where the degree of the decrease in the length of the single period varies obtained using the manufacturing method according to the embodiment of the present invention is the same as a typical optically-anisotropic layer 23 where the length of the single period monotonically decreases.

In circularly polarized light incident into the optically-anisotropic layer 26 having the above-described liquid crystal alignment pattern, an absolute phase changes depending on individual local regions having different orientations of optical axes of the liquid crystal compound 30. In this case, the amount of change in absolute phase in each of the local regions varies depending on the orientations of the optical axes of the liquid crystal compound 30 into which circularly polarized light is incident.

In the optically-anisotropic layer (optical element 10) having the liquid crystal alignment pattern in which the orientation of the optical axis of the liquid crystal compound 30 changes while continuously rotating in the one direction, a diffraction direction of transmitted light depends on the rotation direction of the optical axis of the liquid crystal compound 30. That is, in this liquid crystal alignment pattern, in a case where the rotation direction of the optical axis of the liquid crystal compound 30 is reversed, the diffraction direction of transmitted light is also reversed with respect to the one direction in which the optical axis rotates.

In addition, the diffraction angle of the optically-anisotropic layer 26 increases as the single period decreases. That is, the diffraction of light of the optically-anisotropic layer 26 increases as the single period decreases.

Accordingly, in the optically-anisotropic layer 26 having the concentric liquid crystal alignment pattern, that is, the liquid crystal alignment pattern in which the optical axis changes while continuously rotating in a radial shape, incidence light (light beam) can be diffused or be focused and transmitted depending on the rotation direction of the optical axis of the liquid crystal compound 30 and the turning direction of circularly polarized light to be incident.

The optically-anisotropic layer 26 is formed of a composition including a liquid crystal compound.

In FIG. 7, in order to simplify the drawing and to clarify the configuration of the optical element 10, only the liquid crystal compound 30 (liquid crystal compound molecules) on the surface of the alignment film 24 in the optically-anisotropic layer 26 is shown. However, as conceptually shown in FIG. 8, the first optically-anisotropic layer 26 has a structure in which the aligned liquid crystal compounds 30 are laminated as in an optically-anisotropic layer that is formed using a composition including a typical liquid crystal compound.

In a case where an in-plane retardation value is set as λ/2, the optically-anisotropic layer 26 has a function of a general 22 plate, that is, a function of imparting a retardation of a half wavelength, that is, 180° to two linearly polarized light components in light incident into the optically-anisotropic layer and are orthogonal to each other.

In a plane of the optically-anisotropic layer, the optically-anisotropic layer 26 includes the liquid crystal alignment pattern where the orientation of the optical axis derived from the liquid crystal compound changes while continuously rotating in one direction (for example, directions of the arrow A₁ to the arrow A₄ in FIG. 7) in a radial shape from the inner side toward the outer side.

The optical axis 30A derived from the liquid crystal compound 30 is an axis having the highest refractive index in the liquid crystal compound 30, that is, a so-called slow axis. For example, in a case where the liquid crystal compound 30 is a rod-like liquid crystal compound, the optical axis 30A is along a rod-like major axis direction.

In the following description, the optical axis 30A derived from the liquid crystal compound 30 will also be referred to as “the optical axis 30A of the liquid crystal compound 30” or “the optical axis 30A”.

Hereinafter, the optically-anisotropic layer 26 will be described with reference to an optically-anisotropic layer 26A that includes a liquid crystal alignment pattern where the optical axes 30A change while continuously rotating in one direction indicated by an arrow A as conceptually shown in a plan view of FIG. 9.

Even in the concentric liquid crystal alignment pattern shown in FIG. 7 that includes one direction in which the optical axis changes while continuously rotating in a radial shape from the inner side toward the outer side, the same optical effects as those of the liquid crystal alignment pattern shown in FIG. 9 can be exhibited for the one direction in which the optical axis changes while continuously rotating.

In the optically-anisotropic layer 26A, the liquid crystal compound 30 is two-dimensionally arranged in a plane parallel to the one direction indicated by the arrow A and a Y direction orthogonal to the arrow A direction. In FIGS. 7 and 8 described below, the Y direction is a direction orthogonal to the paper plane.

In the following description, “one direction indicated by the arrow A” will also be simply referred to as “arrow A direction”.

In the optically-anisotropic layer 26 shown in FIG. 7, a circumferential direction of a concentric circle in the concentric liquid crystal alignment pattern corresponds to the Y direction in FIG. 9.

The optically-anisotropic layer 26A has the liquid crystal alignment pattern in which the orientation of the optical axis 30A derived from the liquid crystal compound 30 changes while continuously rotating in the arrow A direction in a plane of the optically-anisotropic layer 26A.

Specifically, “the orientation of the optical axis 30A of the liquid crystal compound 30 changes while continuously rotating in the arrow A direction (the predetermined one direction)” represents that an angle between the optical axis 30A of the liquid crystal compound 30, which is arranged in the arrow A direction, and the arrow A direction varies depending on positions in the arrow A direction, and the angle between the optical axis 30A and the arrow A direction sequentially changes from θ to θ+180° or θ-180° in the arrow A direction.

A difference between the angles of the optical axes 30A of the liquid crystal compound 30 adjacent to each other in the arrow A direction is preferably 45° or less, more preferably 15° or less, and still more preferably less than 15°.

On the other hand, regarding the liquid crystal compound 30 forming the optically-anisotropic layer 26A, the liquid crystal compounds 30 having the same orientation of the optical axes 30A are arranged at regular intervals in the Y direction orthogonal to the arrow A direction, that is, the Y direction orthogonal to the one direction in which the optical axis 30A continuously rotates.

In other words, regarding the liquid crystal compound 30 forming the optically-anisotropic layer 26, in the liquid crystal compounds 30 arranged in the Y direction, angles between the orientations of the optical axes 30A and the arrow A direction are the same.

In the optically-anisotropic layer 26 shown in FIG. 7, a region where the orientations of the optical axes 30A are the same is formed in an annular shape where the centers match with each other, and a concentric liquid crystal alignment pattern is formed.

As in the above-described short line, even in the optically-anisotropic layer 26, in the liquid crystal alignment pattern in which the optical axis 30A continuously rotates in the one direction, a length (distance) over which the optical axis 30A of the liquid crystal compound 30 rotates by 180° is set as a length A of the single period in the liquid crystal alignment pattern.

That is, in the optically-anisotropic layer 26A shown in FIG. 9, the length (distance) over which the optical axis 30A of the liquid crystal compound 30 rotates by 180° in the arrow A direction in which the orientation of the optical axis 30A changes while continuously rotating in a plane is set as the single period Λ in the liquid crystal alignment pattern. In other words, the single period Λ in the liquid crystal alignment pattern is defined by the distance between θ and θ+180° that is a range of the angle between the optical axis 30A of the liquid crystal compound 30 and the arrow A direction.

That is, a distance between centers of two liquid crystal compounds 30 in the arrow A direction is the single period Λ, the two liquid crystal compounds having the same angle in the arrow A direction. Specifically, as shown in FIG. 9, a distance between centers in the arrow A direction of two liquid crystal compounds 30 in which the arrow A direction and the direction of the optical axis 30A match with each other is the single period Λ.

In the optically-anisotropic layer 26A (optically-anisotropic layer 26), in the liquid crystal alignment pattern of the optically-anisotropic layer, the single period Λ is repeated in the arrow A direction, that is, in the one direction in which the orientation of the optical axis 30A changes while continuously rotating.

That is, the optical element 10 is also a transmissive liquid crystal diffraction element (liquid crystal diffractive lens), and the single period Λ is the period (single period) of the diffraction structure as described above.

In the optical element 10 having the concentric liquid crystal alignment pattern where the optical axis 30A continuously rotates in a radial shape, the single period Λ in the optically-anisotropic layer 26 gradually decreases from the inner side (center) toward the outer side as described above.

As described above, in the liquid crystal compounds arranged in the Y direction in the optically-anisotropic layer 26A, the angles between the optical axes 30A and the arrow A direction (the one direction in which the orientation of the optical axis of the liquid crystal compound 30 rotates) are the same. Regions where the liquid crystal compounds 30 in which the angles between the optical axes 30A and the arrow A direction are the same are disposed in the Y direction will be referred to as “regions R”.

In this case, it is preferable that an in-plane retardation (Re) value of each of the regions R is a half wavelength, that is, λ/2. The in-plane retardation is calculated from the product of a difference Δn in refractive index generated by refractive index anisotropy of the region R and the thickness of the optically-anisotropic layer. Here, the difference in refractive index generated by refractive index anisotropy of the region R in the optically-anisotropic layer is defined by a difference between a refractive index of a direction of an in-plane slow axis of the region R and a refractive index of a direction orthogonal to the direction of the slow axis. That is, the difference Δn in refractive index generated by refractive index anisotropy of the region R is the same as a difference between a refractive index of the liquid crystal compound 30 in the direction of the optical axis 30A and a refractive index of the liquid crystal compound 30 in a direction perpendicular to the optical axis 30A in a plane of the region R. That is, the difference Δn in refractive index is the same as the difference in refractive index of the liquid crystal compound.

In the optical element 10 having the liquid crystal alignment pattern where the optical axis 30A continuously rotates in the one direction in a radial shape, the region where the orientations of the optical axes 30A are the same that is formed in an annular shape where the centers match with each other corresponds to the region R in FIG. 9. Regarding this point, the same can also be applied to a reflective optical element 36 including a cholesteric liquid crystal layer described below.

In a case where circularly polarized light is incident into the above-described optically-anisotropic layer 26A, the light is diffracted such that the direction of the circularly polarized light is converted.

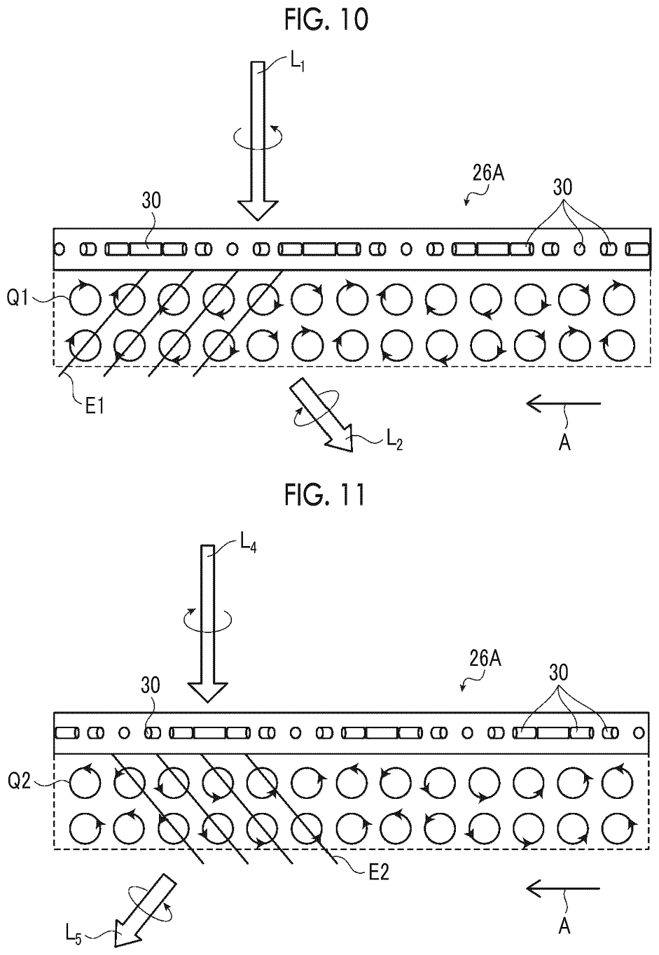

This action is conceptually shown in FIGS. 10 and 11. In the optically-anisotropic layer 26A, the value of the product of the difference in refractive index of the liquid crystal compound and the thickness of the optically-anisotropic layer is λ/2.

As described above, this action is also completely the same in the optical element 10 having the liquid crystal alignment pattern where the optical axis 30A continuously rotates in the one direction in a radial shape.

As shown in FIG. 10, in a case where the value of the product of the difference in refractive index of the liquid crystal compound in the optically-anisotropic layer 26A and the thickness of the optically-anisotropic layer is λ/2 and incidence light L₁ as left circularly polarized light is incident into the optically-anisotropic layer 26A, the incidence light L₁ transmits through the optically-anisotropic layer 26A to be imparted with a retardation of 180°, and the transmitted light L₂ is converted into right circularly polarized light.

In addition, in a case where the incidence light L₁ transmits through the optically-anisotropic layer 26A, an absolute phase thereof changes depending on the orientation of the optical axis 30A of each of the liquid crystal compounds 30. In this case, the orientation of the optical axis 30A changes while rotating in the arrow A direction. Therefore, the amount of change in the absolute phase of the incidence light L₁ varies depending on the direction of the optical axis 30A. Further, the liquid crystal alignment pattern that is formed in the optically-anisotropic layer 26A is a pattern that is periodic in the arrow A direction. Therefore, as shown in FIG. 10, the incidence light L₁ transmitted through the optically-anisotropic layer 26A is imparted with an absolute phase Q1 that is periodic in the arrow A direction corresponding to the orientation of each of the optical axes 30A. As a result, an equiphase surface E1 that is tilted in a direction opposite to the arrow A direction is formed.

Therefore, the transmitted light L₂ is diffracted to be tilted in a direction perpendicular to the equiphase surface E1 and travels in a direction different from a traveling direction of the incidence light L₁. This way, the incidence light L₁ of the left circularly polarized light is converted into the transmitted light L₂ of right circularly polarized light that is tilted by a predetermined angle in the arrow A direction with respect to an incidence direction.

On the other hand, as conceptually shown in FIG. 11, in a case where the value of the product of the difference in refractive index of the liquid crystal compound in the optically-anisotropic layer 26A and the thickness of the optically-anisotropic layer is λ/2 and incidence light L₄ as right circularly polarized light is incident into the optically-anisotropic layer 26A, the incidence light L₄ transmits through the optically-anisotropic layer 26A to be imparted with a retardation of 180° and is converted into transmitted light L₅ of left circularly polarized light.

In addition, in a case where the incidence light L₄ transmits through the optically-anisotropic layer 26A, an absolute phase thereof changes depending on the orientation of the optical axis 30A of each of the liquid crystal compounds 30. In this case, the orientation of the optical axis 30A changes while rotating in the arrow A direction. Therefore, the amount of change in the absolute phase of the incidence light L₄ varies depending on the direction of the optical axis 30A. Further, the liquid crystal alignment pattern that is formed in the optically-anisotropic layer 26A is a pattern that is periodic in the arrow A direction. Therefore, as shown in FIG. 11, the incidence light L₄ transmitted through the optically-anisotropic layer 26A is imparted with an absolute phase Q2 that is periodic in the arrow A direction corresponding to the orientation of each of the optical axes 30A.

Here, the incidence light L₄ is right circularly polarized light. Therefore, the absolute phase Q2 that is periodic in the arrow A direction corresponding to the orientation of the optical axis 30A is opposite to the incidence light L₁ as left circularly polarized light. As a result, in the incidence light L₄, an equiphase surface E2 that is tilted in the arrow A direction opposite to that of the incidence light L₁ is formed.

Therefore, the incidence light L₄ is diffracted to be tilted in a direction perpendicular to the equiphase surface E2 and travels in a direction different from a traveling direction of the incidence light L₄. This way, the incidence light L₄ is converted into the transmitted light L₅ of left circularly polarized light that is tilted by a predetermined angle in a direction opposite to the arrow A direction with respect to an incidence direction.

In the optically-anisotropic layer 26, it is preferable that the in-plane retardation value of the plurality of regions R is a half wavelength. It is preferable that an in-plane retardation Re(550)=Δn₅₅₀×d of the plurality of regions R of the optically-anisotropic layer 26 with respect to the incidence light having a wavelength of 550 nm is in a range defined by the following Expression (1). Here, Δn₅₅₀ represents a difference in refractive index generated by refractive index anisotropy of the region R in a case where the wavelength of incidence light is 550 nm, and d represents the thickness of the optically-anisotropic layer 26.

200 nm≤Δn₅₅₀×d≤350 nm (1).

The optically-anisotropic layer 26 functions as a so-called 22 plate. However, in the present invention, in a case where the substrate 20 and the alignment film 24 are provided, an aspect where a laminate integrally including the substrate 20 and the alignment film 24 functions as a λ/2 plate.

Here, by changing the single period Λ of the liquid crystal alignment pattern formed in the optically-anisotropic layer 26A, diffraction angles of the transmitted light components L₂ and L₅ can be adjusted. Specifically, as the single period Λ of the liquid crystal alignment pattern decreases, light components transmitted through the liquid crystal compounds 30 adjacent to each other more strongly interfere with each other. Therefore, the transmitted light components L₂ and L₅ can be more largely diffracted.

In addition, diffraction angles of the transmitted light components L₂ and L₅ with respect to the incidence light components L₁ and L₄ vary depending on the wavelengths of the incidence light components L₁ and L₄ (the transmitted light components L₂ and L₅). Specifically, as the wavelength of incidence light increases, the transmitted light is largely diffracted. That is, in a case where incidence light is red light, green light, and blue light, the red light is diffracted to the highest degree, and the blue light is diffracted to the lowest degree.

Further, by reversing the rotation direction of the optical axis 30A of the liquid crystal compound 30 that rotates in the arrow A direction, the diffraction direction of transmitted light can be reversed.

The optically-anisotropic layer 26 is formed of a liquid crystal composition including a rod-like liquid crystal compound or a disk-like liquid crystal compound, and has a liquid crystal alignment pattern in which an optical axis of the rod-like liquid crystal compound or an optical axis of the disk-like liquid crystal compound is aligned as described above.

By forming the alignment film 24 having the alignment pattern corresponding to the above-described liquid crystal alignment pattern on the substrate 20 and applying the liquid crystal composition to the alignment film 24, and curing the applied liquid crystal composition, the optically-anisotropic layer formed of the cured layer of the liquid crystal composition can be obtained.

In addition, the liquid crystal composition for forming the optically-anisotropic layer 26 includes a rod-like liquid crystal compound or a disk-like liquid crystal compound and may further include other components such as a leveling agent, an alignment control agent, a polymerization initiator, or an alignment assistant.

In addition, it is preferable that the optically-anisotropic layer 26 has a wide range for the wavelength of incidence light and is formed of a liquid crystal material having a reverse birefringence index dispersion.

### —Rod-Like Liquid Crystal Compound—

As the rod-like liquid crystal compound, an azomethine compound, an azoxy compound, a cyanobiphenyl compound, a cyanophenyl ester compound, a benzoate compound, a phenyl cyclohexanecarboxylate compound, a cyanophenylcyclohexane compound, a cyano-substituted phenylpyrimidine compound, an alkoxy-substituted phenylpyrimidine compound, a phenyldioxane compound, a tolan compound, or an alkenylcyclohexylbenzonitrile compound is preferably used. As the rod-like liquid crystal compound, not only the above-described low molecular weight liquid crystal molecules but also polymer liquid crystal molecules can be used.

In the optically-anisotropic layer 26, it is more preferable that the alignment of the rod-like liquid crystal compound is immobilized by polymerization. Examples of the polymerizable rod-like liquid crystal compound include compounds described in Makromol. Chem., (1989), Vol. 190, p. 2255, Advanced Materials (1993), Vol. 5, p. 107, U.S. Pat. Nos. 4,683,327A, 5,622,648A, 5,770,107A, WO95/22586A, WO95/24455A, WO97/00600A, WO98/23580A, WO98/52905A, JP1989-272551A (JP-H1-272551A), JP1994-16616A (JP-H6-16616A), JP1995-110469A (JP-H7-110469A), JP1999-80081A (JP-H11-80081A), and JP2001-64627. Further, as the rod-like liquid crystal compound, for example, compounds described in JP1999-513019A (JP-H11-513019A) and JP2007-279688A can also be preferably used.

### —Disk-Like Liquid Crystal Compound—

As the disk-like liquid crystal compound, for example, compounds described in JP2007-108732A and JP2010-244038A can be preferably used.

In a case where the disk-like liquid crystal compound is used in the optically-anisotropic layer, the liquid crystal compound 30 rises in the thickness direction in the optically-anisotropic layer, and the optical axis 30A derived from the liquid crystal compound is defined as an axis perpendicular to a disk plane, that is so-called, a fast axis.

In the optically-anisotropic layer 26 shown in FIG. 8, in the thickness direction, the liquid crystal compounds are aligned in the same direction.

However, the optically-anisotropic layer 26 of the optical element 10 manufactured using the manufacturing method according to the embodiment of the present invention is not limited, and the liquid crystal compound 30 is helically twisted and aligned in the thickness direction as in a cholesteric liquid crystal layer 34 described below.

In the optically-anisotropic layer 26, by helically twisting and aligning the liquid crystal compound 30 in the thickness direction, the diffraction efficiency can be improved.

In addition, in the optically-anisotropic layer 26, by helically twisting and aligning the liquid crystal compound 30 in the thickness direction, the wavelength range of the optically-anisotropic layer can also be substantially widened with respect to the wavelength of incidence light. For example, in the optically-anisotropic layer 26, a method of realizing a λ/2 plate having a wide-range pattern by laminating two layers having different twisted directions is disclosed in, for example, JP2014-089476A and can be preferably used in the present invention.

This configuration will be described below.

In the optically-anisotropic layer 26 where the liquid crystal compound 30 is helically twisted and aligned in the thickness direction, a twisted angle of the liquid crystal compound 30 is not limited, and may be a twisted angle where the optically-anisotropic layer 26 does not act as a reflective layer (cholesteric liquid crystal layer).

The twisted angle of the liquid crystal compound 30 is preferably more than 0° and 180° or less and more preferably more than 0° and 90° or less.

This way, the optically-anisotropic layer 26 where the liquid crystal compound 30 is twisted and aligned in the thickness direction can be formed by adding a chiral agent described below to the liquid crystal composition for forming the above-described optically-anisotropic layer 26.

In addition, the twisted angle of the liquid crystal compound 30 can be adjusted by adjusting the kind of the chiral agent to be added and/or the addition amount of the chiral agent.

The optical element 10 shown in FIGS. 7 and 8 includes the substrate 20 and the alignment film 24. However, the optical element manufactured using the manufacturing method according to the embodiment of the present invention, that is, the optical element according to the embodiment of the present invention is not limited to this configuration.

Accordingly, the optical element according to the embodiment of the present invention that is manufactured using the manufacturing method according to the embodiment of the present invention may be configured to include the optically-anisotropic layer 26 and the alignment film 24 by peeling off the substrate 20 from the optical element 10 shown in FIG. 7 and the like, may be configured to include only the optically-anisotropic layer 26 by peeling off the substrate 20 and the alignment film 24 from the optical element 10 shown in FIG. 7 and the like, or may be configured by bonding the optically-anisotropic layer 26 to another support.

Regarding this point, the same can also be applied to the optical element including the cholesteric liquid crystal layer described below.

The above-described optical element 10 is a transmissive optical element 10 through which circularly polarized light transmits and is diffracted. However, the optical element manufactured using the manufacturing method according to the embodiment of the present invention is not limited to this configuration.

That is, the optical element manufactured using the manufacturing method according to the embodiment of the present invention may be a reflective optical element (liquid crystal diffractive lens) including a cholesteric liquid crystal layer.

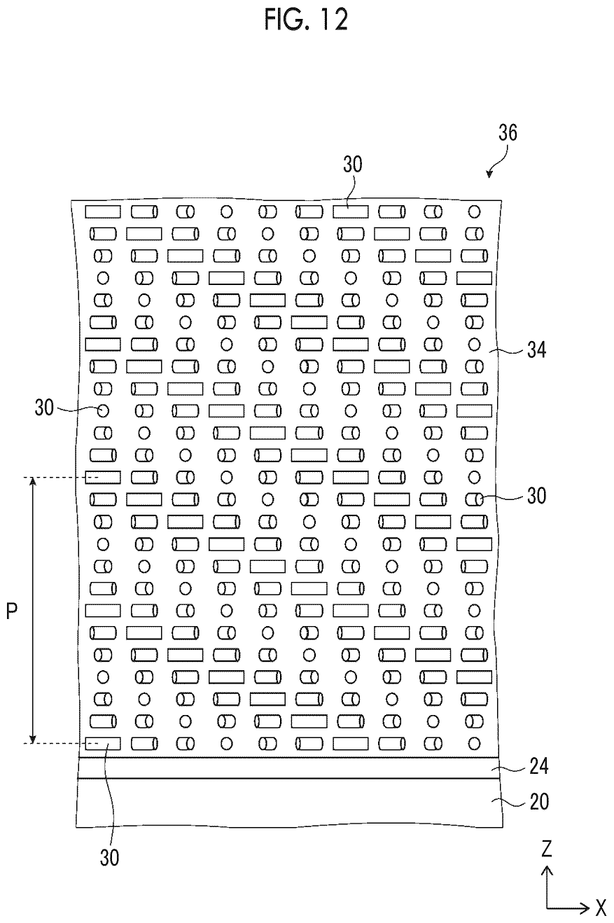

FIG. 12 conceptually shows an example of the reflective optical element manufactured using the manufacturing method according to the embodiment of the present invention. The optical element 36 shown in FIG. 12 adopts many members that are the same as those of the above-described transmissive optical element 10. Accordingly, the same members are represented by the same reference numerals, and different portions will be mainly described below.

FIG. 12 is a diagram conceptually showing a layer configuration of the reflective optical element 36. The optical element 36 includes the substrate 20 and the alignment film 24 described above, and a cholesteric liquid crystal layer 34 that exhibits the action as the reflective optical element 36.

Regarding the liquid crystal alignment pattern of the liquid crystal compound 30 in the cholesteric liquid crystal layer 34, as in the optical element 10, as shown in FIG. 7, the liquid crystal alignment pattern in which the optical axis 30A changes while continuously rotating in the one direction indicated by the arrow A is provided in a radial shape.

In the cholesteric liquid crystal layer 34 having the typical concentric liquid crystal alignment pattern shown in FIG. 12 or the like, the length of the single period monotonically decreases from the inner side toward the outer side.

On the other hand, in the cholesteric liquid crystal layer 34 having the concentric liquid crystal alignment pattern that is obtained using the manufacturing method according to the embodiment of the present invention, the degree of the decrease in the length of the single period increases or varies as in the above-described optically-anisotropic layer 26.

However, regarding the optical action and the like of the optically-anisotropic layer described below, the cholesteric liquid crystal layer 34 where the degree of the decrease in the length of the single period varies obtained using the manufacturing method according to the embodiment of the present invention is also the same as the typical cholesteric liquid crystal layer 34 where the length of the single period monotonically decreases.

FIG. 13 is a schematic diagram showing an alignment state of the liquid crystal compound 30 in a plane of a main surface of the cholesteric liquid crystal layer 34. FIG. 13 shows an alignment state of a facing surface of the cholesteric liquid crystal layer 34 facing the alignment film 24.

As in FIG. 9 described above, in the cholesteric liquid crystal layer 34A shown in FIG. 13, in order to describe the cholesteric liquid crystal layer 34, the liquid crystal alignment pattern in which the optical axis 30A changes while continuously rotating in the one direction indicated by the arrow A is shown. However, even in the liquid crystal alignment pattern that includes one direction in which the optical axis changes while continuously rotating in a radial shape (concentric shape) from an inner side toward an outer side, the same optical effects as those of the liquid crystal alignment pattern shown in FIG. 13 can be exhibited for the one direction in which the optical axis changes while continuously rotating.

In addition, as in FIG. 9 described above, even in FIG. 13, a circumferential direction of a concentric circle in the concentric liquid crystal alignment pattern shown in FIG. 7 corresponds to the Y direction in FIG. 13.

As shown in FIG. 12, the cholesteric liquid crystal layer 34 is a layer obtained by cholesteric alignment of the liquid crystal compound 30. In addition, FIGS. 12 and 13 show an example in which the liquid crystal compound forming the cholesteric liquid crystal layer is a rod-like liquid crystal compound.

In the following description, the cholesteric liquid crystal layer will also be referred to as the liquid crystal layer.

In the optical element 36, the substrate 20 and the alignment film 24 are as described above.

In the optical element 36, the liquid crystal layer 34 (cholesteric liquid crystal layer) having the liquid crystal alignment pattern shown in FIG. 7 is provided on the alignment film 24 having the alignment pattern shown in FIG. 3.

The liquid crystal layer 34 is a cholesteric liquid crystal layer obtained by cholesterically aligning the liquid crystal compound to immobilize a cholesteric liquid crystal phase. In the present example, the cholesteric liquid crystal layer has a liquid crystal alignment pattern in which an orientation of an optical axis derived from a liquid crystal compound changes while continuously rotating in at least one in-plane direction.

As conceptually shown in FIG. 12, the liquid crystal layer 34 has a helical structure in which the liquid crystal compound 30 is helically turned and laminated as in a cholesteric liquid crystal layer obtained by immobilizing a typical cholesteric liquid crystal phase. In the helical structure, a configuration in which the liquid crystal compound 30 is helically rotated once (rotated by 360°) and laminated is set as one helical pitch (helical pitch P), and plural pitches of the helically turned liquid crystal compound 30 are laminated.

As is well known, the cholesteric liquid crystal phase exhibits selective reflectivity with respect to left or right circularly polarized light at a specific wavelength. Whether or not the reflected light is right circularly polarized light or left circularly polarized light is determined depending on a helical twisted direction (sense) of the cholesteric liquid crystal phase. Regarding the selective reflection of the circularly polarized light by the cholesteric liquid crystal phase, in a case where the helical twisted direction of the cholesteric liquid crystal phase is right, right circularly polarized light is reflected, and in a case where the helical twisted direction of the cholesteric liquid crystal phase is left, left circularly polarized light is reflected.

A turning direction of the cholesteric liquid crystal phase can be adjusted by adjusting the kind of the liquid crystal compound that forms the cholesteric liquid crystal layer and/or the kind of the chiral agent to be added.

In addition, a half-width Δλ (nm) of a selective reflection range (circularly polarized light reflection range) where selective reflection is exhibited depends on Δn of the cholesteric liquid crystal phase and the helical pitch P and satisfies a relationship of “Δλ=Δn×helical pitch”. Therefore, the width of the selective reflection range can be controlled by adjusting Δn. An can be adjusted by adjusting a kind of a liquid crystal compound for forming the cholesteric liquid crystal layer and a mixing ratio thereof, and a temperature during alignment immobilization.

Accordingly, regarding the wavelength of light that is reflected (diffracted) by the liquid crystal layer 34, the selective reflection wavelength range of the liquid crystal layer 34 may be appropriately set, for example, by adjusting the helical pitch P of the liquid crystal layer according to each of the liquid crystal diffraction elements.

As shown in FIG. 13, in the liquid crystal layer 34A, the liquid crystal compounds 30 are arranged in the arrow A direction and the Y direction orthogonal to the arrow A direction. The orientation of the optical axis 30A of the liquid crystal compound 30 changes while continuously rotating in the one in-plane direction in a plane, that is, in the arrow A direction. In addition, in the Y direction, the liquid crystal compounds 30 in which the orientations of the optical axes 30A are the same are arranged at regular intervals.

“The orientation of the optical axis 30A of the liquid crystal compound 30 changes while continuously rotating in the one in-plane direction” represents that as in the optically-anisotropic layer 26, angles between the optical axes 30A of the liquid crystal compounds 30 and the arrow A direction vary depending on positions in the arrow A direction and the angle between the optical axis 30A and the arrow A direction gradually changes from θ to θ+180° or θ-180° in the arrow A direction. That is, in each of the plurality of liquid crystal compounds 30 arranged in the arrow A direction, as shown in FIG. 13, the optical axis 30A changes in the arrow A direction while rotating on a given angle basis.

A difference between the angles of the optical axes 30A of the liquid crystal compound 30 adjacent to each other in the arrow A direction is preferably 45° or less, more preferably 15° or less, and still more preferably less than 15°.

As in the above-described optically-anisotropic layer 26, even in the liquid crystal layer 34, in the liquid crystal alignment pattern of the liquid crystal compound 30, a length (distance) over which the optical axis 30A of the liquid crystal compound 30 rotates by 180° in the arrow A direction in which the optical axis 30A changes while continuously rotating in a plane is set as a length A of the single period in the liquid crystal alignment pattern.

In the liquid crystal alignment pattern of the liquid crystal layer 34A, the single period Λ is repeated in the arrow A direction, that is, in the one direction in which the orientation of the optical axis 30A changes while continuously rotating. The optical element 36 is a reflective liquid crystal diffraction element, and the single period Λ is the period (single period) of the diffraction structure as described above.

On the other hand, in the liquid crystal compound 30 forming the liquid crystal layer 34A, the orientations of the optical axes 30A are the same in the direction (in FIG. 13, the Y direction) orthogonal to the arrow A direction, that is, the Y direction orthogonal to the one direction in which the optical axis 30A continuously rotates. In the liquid crystal alignment pattern shown in FIG. 7, as described above, the Y direction is a circumferential direction of a concentric circle.

In other words, in the liquid crystal compound 30 forming the liquid crystal layer 34, angles between the optical axes 30A of the liquid crystal compound 30 and the arrow A direction (X direction) are the same in the Y direction.

In a case where a cross section of the liquid crystal layer 34 shown in FIG. 12 in the X-Z direction is observed with a scanning electron microscope (SEM), a stripe pattern where an arrangement direction in which bright lines 42 and dark lines 44 are alternately arranged as shown in FIG. 14 is tilted at a predetermined angle with respect to the main surface (X-Y plane) is observed.

Basically, the interval of the bright lines 42 and the dark lines 44 depends on the helical pitch P of the cholesteric liquid crystal layer.

Accordingly, the wavelength range of light that is selectively reflected by the cholesteric liquid crystal layer correlates to the interval of the bright lines 42 and the dark lines 44. That is, as the interval of the bright lines 42 and the dark lines 44 increases, the helical pitch P increases. Therefore, the wavelength range of light that is selectively reflected by the cholesteric liquid crystal layer increases. Conversely, as the interval of the bright lines 42 and the dark lines 44 decreases, the helical pitch P decreases. Therefore, the wavelength range of light that is selectively reflected by the cholesteric liquid crystal layer decreases.

In the cholesteric liquid crystal layer, basically, a structure in which the bright line 42 and the dark line 44 are repeated twice corresponds to the helical pitch P. Accordingly, in the cross section observed with an SEM, an interval between the bright lines 42 adjacent to each other or between the dark lines 44 adjacent to each other in a normal direction (vertical direction) of lines formed by the bright lines 42 or the dark lines 44 corresponds to a ½ pitch of the helical pitch P.

That is, the helical pitch P may be measured by setting the interval between the bright lines 42 or between the dark lines 44 in the normal direction with respect to the lines as a ½ pitch.

Hereinafter, an action of diffraction of the liquid crystal layer 34A will be described.

In a cholesteric liquid crystal layer of the related art, a helical axis derived from a cholesteric liquid crystal phase is perpendicular to the main surface, and a reflecting surface thereof is parallel to the main surface. In addition, the optical axis of the liquid crystal compound is not tilted with respect to the main surface. In other words, the optical axis is parallel to the main surface. Accordingly, in a case where the X-Z plane of the cholesteric liquid crystal layer in the related art is observed with an SEM, an arrangement direction in which bright lines and dark lines are alternately arranged is perpendicular to the main surface.

The cholesteric liquid crystal phase has specular reflectivity. Therefore, in a case where light is incident from the normal direction into the cholesteric liquid crystal layer, the light is reflected in the normal direction.

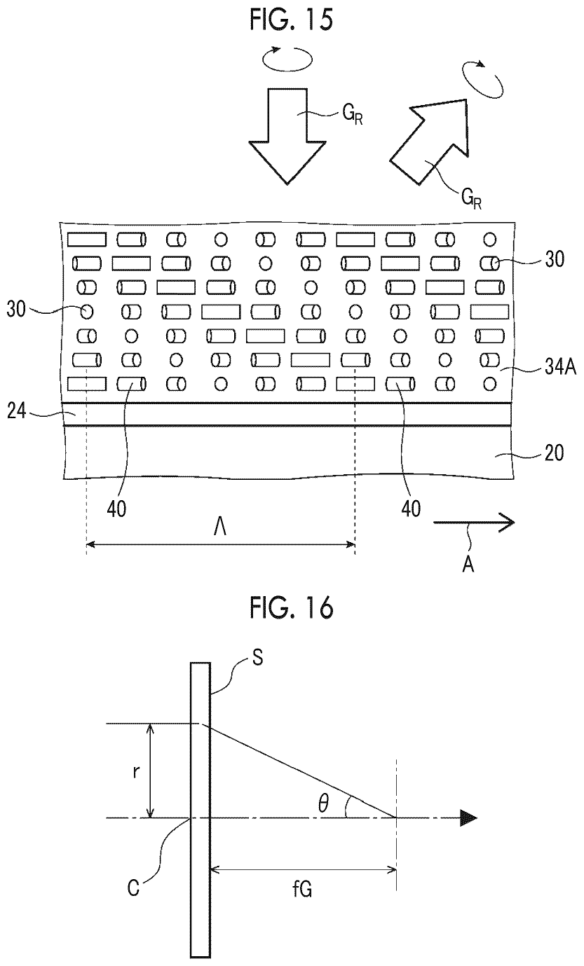

On the other hand, the liquid crystal layer 34A reflects incident light in a state where the light is tilted in the arrow A direction with respect to the specular reflection. The liquid crystal layer 34A has the liquid crystal alignment pattern in which the optical axis 30A changes while continuously rotating in the arrow A direction (the predetermined one direction) in a plane. Hereinafter, the description will be made with reference to FIG. 15.

For example, it is assumed that the liquid crystal layer 34A is a cholesteric liquid crystal layer that selectively reflects right circularly polarized light G_{R} of green light. Accordingly, in a case where light is incident into the liquid crystal layer 34A, the liquid crystal layer 34A reflects only right circularly polarized light G_{R} of green light and allows transmission of the other light.

Here, in the liquid crystal layer 34A, the optical axis 30A of the liquid crystal compound 30 changes while rotating in the arrow A direction (the one direction).

The liquid crystal alignment pattern formed in the liquid crystal layer 34A is a pattern that is periodic in the arrow A direction. Therefore, as conceptually shown in FIG. 15, the right circularly polarized light G_{R} of green light incident into the liquid crystal layer 34A is reflected (diffracted) in a direction corresponding to the period of the liquid crystal alignment pattern, and the reflected right circularly polarized light G_{R} of green light is reflected (diffracted) in a direction tilted with respect to the XY plane (the main surface of the cholesteric liquid crystal layer) in the arrow A direction.

In addition, in a case where circularly polarized light having the same wavelength and the same turning direction is reflected, by reversing the rotation direction of the optical axis 30A of the liquid crystal compound 30 toward the arrow A direction, a reflection direction of the circularly polarized light can be reversed.

That is, in FIGS. 12 and 13, the rotation direction of the optical axis 30A toward the arrow A direction is clockwise, and one circularly polarized light is reflected in a state where the light is tilted in the arrow A direction. By setting the rotation direction of the optical axis 30A to be counterclockwise, the circularly polarized light is reflected in a state where the light is tilted in a direction opposite to the arrow A direction.

Further, in the liquid crystal layer having the same liquid crystal alignment pattern, the reflection direction is reversed by adjusting the helical turning direction of the liquid crystal compound 30, that is, the turning direction of circularly polarized light to be reflected.

For example, in a case where the helical turning direction of the liquid crystal layer is right-twisted, the liquid crystal layer selectively reflects right circularly polarized light, and has the liquid crystal alignment pattern in which the optical axis 30A rotates clockwise in the arrow A direction. As a result, the right circularly polarized light is reflected in a state where the light is tilted in the arrow A direction.

In addition, for example, in a case where the helical turning direction of the liquid crystal layer is left-twisted, the liquid crystal layer selectively reflects left circularly polarized light, and has the liquid crystal alignment pattern in which the optical axis 30A rotates clockwise in the arrow A direction. As a result, the left circularly polarized light is reflected in a state where the light is tilted in a direction opposite to the arrow A direction.

Accordingly, the optical element 36 can be used as a convex mirror that reflects incidence light to diffuse the light or a concave mirror that reflects incidence light to focus the light depending on the rotation direction of the optical axis 30A from an inner side toward an outer side in the liquid crystal layer 34 and the turning direction of circularly polarized light to be selectively reflected from the liquid crystal layer 34.

As described above, in the liquid crystal layer 34 that acts as the reflective optical element 36, in the liquid crystal alignment pattern of the liquid crystal compound 30, the single period Λ as the length over which the optical axis 30A of the liquid crystal compound 30 rotates by 180° is the period (single period) of the diffraction structure. In addition, in the liquid crystal layer 34, the one direction (arrow A direction) in which the optical axis 30A of the liquid crystal compound 30 changes while rotating is the periodic direction of the diffraction structure.

In the liquid crystal layer having the liquid crystal alignment pattern, as the single period Λ decreases, the diffraction angle of reflected light with respect to the incidence light increases. That is, as the single period Λ decreases, incidence light can be largely diffracted to be reflected in a direction that is largely different from specular reflection.

In the present invention, the single period Λ of the liquid crystal layer 34 is not limited, and may be appropriately set depending on the use of the optical element 36 or the like.

The single period Λ of the liquid crystal layer 34 is preferably 0.1 to 20 μm and more preferably 0.1 to 10 μm.

The liquid crystal layer 34 can be formed by immobilizing a liquid crystal phase in a layer shape, the liquid crystal phase obtained by aligning the liquid crystal compound 30 in a predetermined alignment state. For example, the cholesteric liquid crystal layer can be formed by immobilizing a cholesteric liquid crystal phase in a layer shape.

The structure in which a cholesteric liquid crystal phase is immobilized may be a structure in which the alignment of the liquid crystal compound as a liquid crystal phase is immobilized. Typically, the structure in which a liquid crystal phase is immobilized is preferably a structure which is obtained by making the polymerizable liquid crystal compound to be in a state where a predetermined liquid crystal phase is aligned, polymerizing and curing the polymerizable liquid crystal compound with ultraviolet irradiation, heating, or the like to form a layer having no fluidity, and concurrently changing the state of the polymerizable liquid crystal compound into a state where the alignment state is not changed by an external field or an external force.

The structure in which a liquid crystal phase is immobilized is not particularly limited as long as the optical characteristics of the liquid crystal phase are maintained, and the liquid crystal compound 30 in the liquid crystal layer does not necessarily exhibit liquid crystallinity. For example, the molecular weight of the polymerizable liquid crystal compound may be increased by a curing reaction such that the liquid crystallinity thereof is lost.

Regarding this point, the same can also be applied to the above-described optically-anisotropic layer 26.

Examples of a material used for forming the liquid crystal layer 34 include a liquid crystal composition including a liquid crystal compound. It is preferable that the liquid crystal compound is a polymerizable liquid crystal compound.

Examples of the liquid crystal composition for forming the (cholesteric) liquid crystal layer 34 include a liquid crystal composition obtained by adding a chiral agent for helically aligning the liquid crystal compound 30 to the liquid crystal composition for forming the optically-anisotropic layer 26 of the above-described transmissive optical element 36.

### —Chiral Agent (Optically Active Compound)—

The chiral agent has a function of causing a helical structure of a cholesteric liquid crystal phase to be formed. The chiral agent may be selected depending on the purpose because a helical twisted direction or a helical pitch P derived from the compound varies.

The chiral agent is not particularly limited, and a well-known compound (for example, Liquid Crystal Device Handbook (No. 142 Committee of Japan Society for the Promotion of Science, 1989), Chapter 3, Article 4-3, chiral agent for twisted nematic (TN) or super twisted nematic (STN), p. 199), isosorbide, or an isomannide derivative can be used.

In general, the chiral agent includes a chiral carbon atom. However, an axially chiral compound or a planar chiral compound not having a chiral carbon atom can also be used as the chiral agent. Examples of the axially chiral compound or the planar chiral compound include binaphthyl, helicene, paracyclophane, and derivatives thereof. The chiral agent may include a polymerizable group. In a case where both the chiral agent and the liquid crystal compound have a polymerizable group, a polymer which includes a repeating unit derived from the polymerizable liquid crystal compound and a repeating unit derived from the chiral agent can be formed due to a polymerization reaction of a polymerizable chiral agent and the polymerizable liquid crystal compound. In this aspect, it is preferable that the polymerizable group in the polymerizable chiral agent is the same as the polymerizable group in the polymerizable liquid crystal compound. Accordingly, the polymerizable group of the chiral agent is preferably an unsaturated polymerizable group, an epoxy group, or an aziridinyl group, more preferably an unsaturated polymerizable group, and still more preferably an ethylenically unsaturated polymerizable group.

In addition, the chiral agent may be a liquid crystal compound.

In a case where the chiral agent includes a photoisomerization group, a pattern having a desired reflection wavelength corresponding to a luminescence wavelength can be formed by irradiation of an actinic ray or the like through a photo mask after coating and alignment, which is preferable. As the photoisomerization group, an isomerization portion of a photochromic compound, an azo group, an azoxy group, or a cinnamoyl group is preferable. Specific examples of the compound include compounds described in JP2002-80478A, JP2002-80851A, JP2002-179668A, JP2002-179669A, JP2002-179670A, JP2002-179681A, JP2002-179682A, JP2002-338575A, JP2002-338668A, JP2003-313189A, and JP2003-313292A.

The content of the chiral agent in the liquid crystal composition is preferably 0.01 to 200 mol % and more preferably 1 to 30 mol % with respect to the content molar amount of the liquid crystal compound.

In a case where the liquid crystal layer 34 is formed, it is preferable that the liquid crystal layer 34 is formed by applying the liquid crystal composition to a surface where the liquid crystal layer 34 is to be formed, aligning the liquid crystal compound 30 to a state of a desired liquid crystal phase, and curing the liquid crystal compound 30.

That is, in a case where the cholesteric liquid crystal layer is formed on the alignment film 24, it is preferable that the liquid crystal layer 34 obtained by immobilizing a cholesteric liquid crystal phase is formed by applying the liquid crystal composition to the alignment film 24, aligning the liquid crystal compound 30 to a state of a cholesteric liquid crystal phase, and curing the liquid crystal compound 30.

The applied liquid crystal composition is optionally dried and/or heated and then is cured to form the liquid crystal layer. In the drying and/or heating step, the liquid crystal compound 30 in the liquid crystal composition only has to be aligned to a cholesteric liquid crystal phase. In the case of heating, the heating temperature is preferably 200° C. or lower and more preferably 130° C. or lower.

The aligned liquid crystal compound 30 is optionally further polymerized. Regarding the polymerization, thermal polymerization or photopolymerization using light irradiation may be performed, and photopolymerization is preferable. Regarding this point, the same can also be applied to the above-described optically-anisotropic layer 26.

Regarding the light irradiation, ultraviolet light is preferably used. The irradiation energy is preferably 20 mJ/cm² to 50 J/cm² and more preferably 50 to 1500 mJ/cm². In order to promote a photopolymerization reaction, light irradiation may be performed under heating conditions or in a nitrogen atmosphere. The wavelength of irradiated ultraviolet light is preferably 250 to 430 nm.

The thickness of the liquid crystal layer 34 is not particularly limited, and the thickness with which a required light reflectivity can be obtained may be appropriately set depending on the use of the optical element, the light reflectivity required for the liquid crystal layer, the material for forming the liquid crystal layer 34, and the like.

The optical element (diffraction element) according to the embodiment of the present invention is basically manufactured using the method of manufacturing an optical element according to the embodiment of the present invention. Accordingly, the optical element according to the embodiment of the present invention is an optical element that diffracts incidence light and emits the diffracted light, the optical element including: a liquid crystal layer that concentrically has a liquid crystal alignment pattern where an orientation of an optical axis derived from a liquid crystal compound changes while continuously rotating in at least one in-plane direction.

In addition, in a case where the optical element according to the embodiment of the present invention is a transmissive type including the optically-anisotropic layer 26, the optical element refracts incident light by diffraction and focuses the refracted light. In a case where the optical element according to the embodiment of the present invention is a reflective type including the cholesteric liquid crystal layer 34, the optical element reflects incident light by diffraction and focuses the reflected light. That is, in a case where the optical element according to the embodiment of the present invention is a liquid crystal diffraction element and a transmissive type, the optical element is, for example, a liquid crystal diffractive lens. In addition, in the optical element according to the embodiment of the present invention, in the liquid crystal alignment pattern of the liquid crystal layer, the length of the single period over which the orientation of the optical axis derived from the liquid crystal compound rotates by 180° gradually changes. Specifically, in the optical element according to the embodiment of the present invention, in the liquid crystal alignment pattern of the liquid crystal layer, the length of the single period over which the orientation of the optical axis derived from the liquid crystal compound rotates by 180° increases or gradually changes instead of the inverse-proportional monotonic decrease. In the optical element according to the embodiment of the present invention, a region where the length of the single period Λ in the liquid crystal alignment pattern increases may be included or may not be included.

Therefore, as described above, in a case where the focal length of the optical element according to the embodiment of the present invention is represented by fG, the focal length fG continuously changes in the direction from the center toward the outer side of the concentric circle in the liquid crystal alignment pattern, that is, from the center of the concentric circle toward the radial direction. In the optical element according to the embodiment of the present invention having the concentric liquid crystal alignment pattern, typically, the center of the concentric circle in the liquid crystal alignment pattern is the optical axis. Accordingly, in the optical element according to the embodiment of the present invention, the focal length fG continuously changes from the optical axis toward the outer side.

In the optical element according to the embodiment of the present invention, as the continuous change in the focal length, various aspects can be used. That is, in the optical element according to the embodiment of the present invention, the focal length may continuously change over the entire area in the direction from the center toward the outer side of the concentric circle. Alternatively, in the optical element according to the embodiment of the present invention, a region where the focal length continuously changes in the direction from the center toward the outer side of the concentric circle and a region where the focal length is constant in the direction from the center toward the outer side of the concentric circle may be mixed.

Here, in the optical element according to the embodiment of the present invention, in a case where the focal length fG continuously changes in the direction from the center toward the outer side of the concentric circle in the liquid crystal alignment pattern, a maximum value of the focal length fG is represented by fGmax, and a minimum value of the focal length fG is represented by fGmin, a ratio “fGmax/fGmin” of the maximum value fGmax to the minimum value fGmin is more than 1.1.

With the above-described configuration, the optical element according to the embodiment of the present invention can control a traveling direction of light at each of positions in a plane direction of the optical element. Therefore, in a case where the optical element according to the embodiment of the present invention is used, for example, for an HMD such as AR glasses or VR goggles as described above, the incidence angle of light into each of members forming the optical system of the HMD can be optimized, and a high-quality image can be more efficiently displayed.

In the optical element according to the embodiment of the present invention, the ratio “fGmax/fGmin” is preferably 1.2 or more and more preferably 1.3 or more.

In addition, in the optical element according to the embodiment of the present invention, the upper limit of the ratio “fGmax/fGmin” is not limited, and is preferably 200 or less in consideration of easy formation of the alignment pattern, the accuracy as a lens, and the like.

In the optical element according to the embodiment of the present invention, the maximum value fGmax and the minimum value fGmin of the focal length fG are measured using the following method to calculate the ratio “fGmax/fGmin”.

As conceptually shown in FIG. 16, the single period Λ (in-plane pitch A) of the liquid crystal alignment pattern is measured at intervals of 1 mm in the entire area from a center C (optical axis) of a concentric circle of an optical element S as a measurement target (sample) toward the outer side, that is, one direction of the radial direction. The single period Λ may be measured using an optical microscope.

In addition, for each of the intervals of 1 mm at which the single period Λ is measured, a distance r from the center toward an end part direction, a wavelength 2, and the measured single period Λ are used to calculate the focal length fG for each of the distances r from the following expression. The wavelength λ may be appropriately set depending on the wavelength of light as a target of the optical element S and may be, for example, 530 nm.

sin θ=λ/Λ

tan θ=r/fG

Based on the focal length fG calculated as described above, the maximum value fGmax and the minimum value fGmin of the focal length fG are selected to calculate the ratio “fGmax/fGmin”.

In addition, by using the measuring method, it can be verified that the focal length fG continuously changes in the direction from the center toward the outer side of the concentric circle in the liquid crystal alignment pattern.

As described above, according to the present invention, unlike Junyu Zou et al., Doubling the optical efficiency of VR systems with a directional backlight and a diffractive deflection film, Vol. 29, No. 13/21 Jun. 2021/Optics Express 20673, JP2010-525395A, and the like, an alignment film for obtaining an optical element that includes regions where the focal length continuously changes without including a non-uniform boundary region (boundary) or the like can be simply formed with high productivity.

In addition, although described below in Examples, in the direct drawing exposure method described in JP2015-532468A and Jihwan Kim et al., Fabrication of ideal geometric-phase holograms with arbitrary wavefronts, Optica Vol. 2, Issue 11, pp. 958-964 (2015), in a case where the single period in the alignment pattern is fine, disorder is likely to occur in the alignment pattern. In particular, in the vicinity of an end part where the single period needs to be short, disorder is likely to occur in the alignment pattern. On the other hand, as described above, according to the present invention where the alignment film is formed by the interference exposure using the focusing element 58 (focal point-variable focusing element) where the focal length continuously changes in the direction orthogonal to the optical axis, the disorder of the alignment pattern can be significantly suppressed.

Therefore, the optical element according to the embodiment of the present invention can significantly suppress the generation of zero-order diffracted light and the generation of diffracted light that is generated between first-order diffracted light and zero-order diffracted light and has a smaller diffraction angle than first-order light. As a result, in the optical element according to the embodiment of the present invention, the occurrence of an unnecessary image called a ghost, multiple images, and the like can be suppressed.

In the optical element according to the embodiment of the present invention, at a position where a ratio of an intensity of zero-order light to an intensity of first-order diffracted light in a plane of the optical element is the maximum, in a case where the ratio of the intensity of the zero-order light to the intensity of the first-order light is represented by Rmax, the ratio Rmax of the zero-order light is 3% or less.

That is, in the optical element according to the embodiment of the present invention, even at the position where the ratio of the intensity of the zero-order light to the intensity of the first-order light in the plane is the maximum, the intensity of the zero-order light is 3% or less with respect to that of the first-order light.

Further, in the optical element according to the embodiment of the present invention, in a case where a ratio of an intensity of a diffracted light component having a maximum intensity among diffracted light components having diffraction angles less than a diffraction angle of first-order light to an intensity of first-order light is represented by a ratio Xmax, the ratio Xmax is 3% or less at a position where the ratio Xmax is the maximum in a plane of the diffraction element.

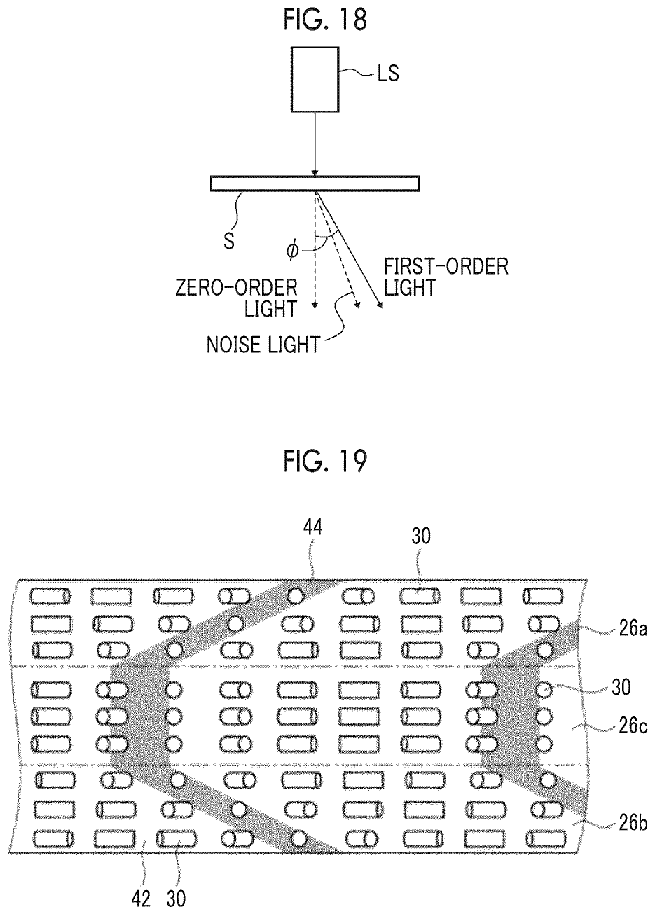

In the diffraction element, one or more light components having a smaller diffraction angle than first-order light may be generated between first-order light and zero-order light (refer to FIG. 18). The light generated between first-order light and zero-order light can be referred to as so-called noise light during diffraction of light.

That is, in the optical element according to the embodiment of the present invention, in a case where the ratio of the intensity of the noise light having the maximum intensity to the intensity of the first-order light is represented by the ratio Xmax, the ratio Xmax is 3% or less at a position where the ratio Xmax is the maximum in a plane of the diffraction element. That is, in the optical element according to the embodiment of the present invention, even at the position where the ratio of the intensity of the noise light to the intensity of the first-order light in the plane is the maximum, the intensity of the noise light is 3% or less with respect to that of the first-order light.

In the following description, the ratio Xmax at the position where the ratio Xmax is the maximum in the plane of the diffraction element will also be referred to as “the maximum ratio Xmax of the noise light” for convenience of description.

Zero-order light is one large cause for the above-described ghost. In addition, the noise light is one large cause for multiple images. On the other hand, in the optical element according to the embodiment of the present invention having the above-described configuration, the intensity of zero-order light to the intensity of first-order light is low, and the intensity of noise light to the intensity of first-order light is also low.

Therefore, in the optical element according to the embodiment of the present invention, the occurrence of ghost, multiple images, and the like can be suitably suppressed as described above.

In a case where the ratio Rmax of the zero-order light exceeds 3%, there is an inconvenience in that, for example, a ghost cannot be sufficiently suppressed.

The ratio Rmax of the zero-order light is preferably 2% or less and more preferably 1% or less.

In a case where the maximum ratio Xmax of the noise light exceeds 3%, there is an inconvenience in that, for example, multiple images cannot be sufficiently suppressed.

The maximum ratio Xmax of the noise light is preferably 2% or less and more preferably 1% or less.

In the optical element according to the embodiment of the present invention, the ratio Rmax of the zero-order light is measured as follows.

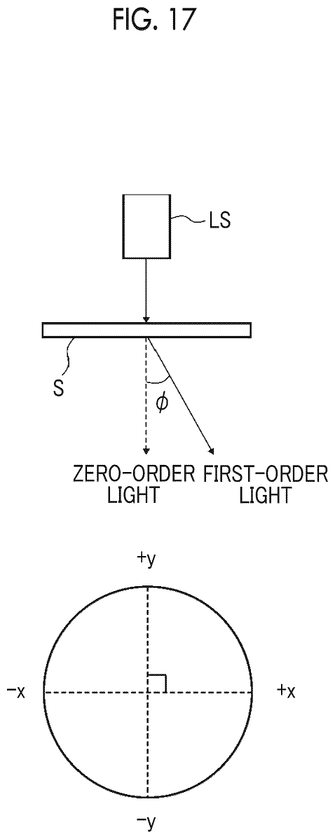

As conceptually shown in FIG. 17, measurement light from a light source LS is caused to be incident from the normal direction into the optical element S as a measurement target (sample), and the intensity of first-order light that is appropriately diffracted (refracted) by the optical element S and the intensity of zero-order light transmitted straight through the optical element S are measured by a photodetector.

As conceptually shown in the lower section of FIG. 17, the measurement of the intensities of the first-order light and the zero-order light is measured at intervals of 1 mm in a ±x direction and a ±y direction orthogonal to the x direction around a center of a concentric circle, that is, an optical axis. In addition, at each of the positions where the measurement is performed, the ratio of the intensity of the zero-order light to the intensity of the first-order light is calculated.

As a result, in a plane of the optical element S, a position where the ratio of the intensity of the zero-order light to the intensity of the first-order light is the maximum is detected, and the ratio of the intensity of the zero-order light to the intensity of the first-order light at this position, that is, the ratio Rmax of the zero-order light is detected.

The measurement position of the first-order light is determined as follows.

First, at the incidence position of the measurement light from the light source LS in the measurement at each of the intervals of 1 mm, the single period Λ (in-plane pitch A) of the liquid crystal alignment pattern is measured with an optical microscope.

the measurement result of the single period Λ, the wavelength λ of the measurement light emitted from the light source LS, and an incidence angle din of the measurement light are used to calculate an emission angle ϕout of the first-order light from the following expression, and the intensity of light at the emission angle ϕout is measured as the intensity of the first-order light.

sin ϕout=λ/Λ+sin ϕin

Λ=λ/(sin ϕout−sin ϕin)

In the measurement of the ratio Rmax of the zero-order light, the wavelength λ of the measurement light may be appropriately set depending on the wavelength of light as a target of the optical element S and may be, for example, 530 nm. In addition, the position of the photodetector is not also limited and, for example, is a position at a distance of 30 cm from the optical element S.

In addition, in the optical element according to the embodiment of the present invention, the maximum ratio Xmax of the noise light is measured as follows.

That is, in the above-described measurement of the ratio Rmax of the zero-order light, an intensity of a noise light component having the maximum intensity among noise light components having diffraction angles less than that of first-order light present between first-order light and zero-order light is measured, and the ratio Xmax of the intensity of the noise light component to the intensity of the first-order light is calculated.

As a result, in a plane of the optical element S, the ratio Xmax at a position where the ratio Xmax of the noise light component to the first-order light is the maximum is obtained as the maximum ratio Xmax of the noise light.

All the methods of measuring the ratio “fGmax/fGmin”, the ratio Rmax of the zero-order light, and the maximum ratio Xmax of the noise light have been described using a case where the optical element according to the embodiment of the present invention is a transmissive optical element (liquid crystal diffractive lens) as an example.

However, even in a case where the optical element according to the embodiment of the present invention is a reflective optical element including a cholesteric liquid crystal layer or the like, the ratio “fGmax/fGmin”, the ratio Rmax of the zero-order light, and the maximum ratio Xmax of the noise light may be measured based on the methods shown in FIGS. 16 to 18, for example, using a method of causing measurement light to be incident from an oblique direction to the normal line.

In the optical element according to the embodiment of the present invention, Δn (birefringence) of the liquid crystal layer is not limited and is preferably 0.2 to 0.5.

It is preferable that Δn (birefringence) of the liquid crystal layer is 0.2 to 0.5, zero-order light from the viewpoints that, for example, zero-order light can be suppressed and the diffraction efficiency can be improved.

Δn of the liquid crystal layer is more preferably 0.24 to 0.45.

Δn of the liquid crystal layer may be measured as follows.

First, a liquid crystal composition for forming a liquid crystal layer is applied to a support with an alignment film for retardation measurement that is separately prepared. Next, the liquid crystal compound is aligned such that a director thereof is parallel to the support, and is irradiated with ultraviolet light to be immobilized.

A retardation value and a film thickness of the liquid crystal layer (liquid crystal immobilized layer) (cured layer)) obtained as described above are measured, and Δn of the liquid crystal layer can be calculated by dividing the retardation value by the film thickness. The retardation value of the liquid crystal layer may be measured by performing the measurement a desired wavelength using Axoscan (manufactured by Axometrix Inc.). On the other hand, the film thickness of the liquid crystal layer may be measured using an SEM.

As described above, in a case where the optical element according to the embodiment of the present invention is a transmissive type (liquid crystal diffractive lens), the liquid crystal compound 30 in the optically-anisotropic layer 26, that is, the liquid crystal layer may be helically twisted and aligned in the thickness direction. By providing the optically-anisotropic layer where the liquid crystal compound is twisted and aligned as described above, the diffraction efficiency can be improved.

This way, in a case where the liquid crystal compound in the optically-anisotropic layer is twisted and aligned in the thickness direction, it is preferable that the optical element according to the embodiment of the present invention includes two or more optically-anisotropic layers where the liquid crystal compound is twisted and aligned in the thickness direction.

Here, as described above, in the optical element according to the embodiment of the present invention, the liquid crystal layer (optically-anisotropic layer 26) has a concentric liquid crystal alignment pattern where an optical axis derived from the liquid crystal compound changes while continuously rotating in at least one direction.

In the optically-anisotropic layer having the liquid crystal alignment pattern, in a case where a cross section taken along the thickness direction along the one direction in which the optical axis rotates is observed with an SEM, in the cross sectional image, the bright lines 42 and the dark lines 44 corresponding to the orientation of the liquid crystal compound are observed as in the above-described cholesteric liquid crystal layer (refer to FIG. 19).

Hereinafter, the bright lines 42 and the dark lines 44 observed in the cross sectional SEM image will also be simply referred to as the bright lines 42 and the dark lines 44 or the bright and dark lines.

This way, in the optically-anisotropic layer where the liquid crystal compound is twisted and aligned in the thickness direction, a tilt angle of the bright and dark lines with respect to the main surface varies depending on a length in the thickness direction over which a helical pitch, that is, a helix rotates by 360°. Specifically, as the helical pitch increases, the tilt angle of the bright and dark lines with respect to the main surface increases, and in a case where the liquid crystal compound is not twisted and aligned, the bright and dark lines match with the thickness direction. In other words, in a case where the helical twisted angle of the liquid crystal compound decreases, the tilt angle of the bright and dark lines with respect to the main surface increases, and as the helical twisted angle of the liquid crystal compound increases, the tilt angle of the bright and dark lines with respect to the main surface decreases.

In addition, in a case where the helical twisted direction of the liquid crystal compound is reversed, the tilt direction of the bright and dark lines with respect to the main surface is reversed. That is, in a case where the helical twisted direction of the liquid crystal compound is right-twisted or left-twisted, for example, the tilt direction of the bright and dark lines with respect to the main surface rises to the right or to the left.

In a case where the optical element according to the embodiment of the present invention includes the optically-anisotropic layer where the liquid crystal compound is twisted and aligned in the thickness direction, it is preferable that the optically-anisotropic layer includes a plurality of optically-anisotropic layers where tilts of the bright and dark lines with respect to the main surface are different. The tilts of the bright and dark lines with respect to the main surface being different represent, for example, a configuration where tilt angles with respect to the main surface are different or a configuration where tilt directions with respect to the main surface are different. In particular, a configuration including optically-anisotropic layers where tilt directions of the bright and dark lines with respect to the main surface are different is suitably used.

In particular, in a case where the optical element according to the embodiment of the present invention includes the optically-anisotropic layer where the liquid crystal compound is twisted and aligned in the thickness direction, it is preferable that the optical element includes at least two optically-anisotropic layers where the liquid crystal compound is twisted and aligned in the thickness direction and includes at least three optically-anisotropic layers where the bright and dark lines with respect to the main surface are different.

Further, in the configuration including three or more layers, as conceptually shown in FIG. 19, it is more preferable that, in a first optically-anisotropic layer 26a and a second optically-anisotropic layer 26b between which a third optically-anisotropic layer 26c is interposed, tilt directions of the bright lines 42 and the dark lines 44 are opposite to each other, and a tilt angle of the bright and dark lines of the third optically-anisotropic layer 26c with respect to the main surface is more than that of the two layers. In this configuration, it is preferable that the bright and dark lines of the third optically-anisotropic layer 26c are close to the thickness direction, and it is more preferable that the bright and dark lines of the third optically-anisotropic layer 26c match with the thickness direction, that is, the liquid crystal compound is not twisted and aligned in the thickness direction.

The above-described configuration is preferable from the viewpoint that, for example, the diffraction efficiency can be further improved and the generation of zero-order light can be suppressed.

Hereinabove, the exposure system, the method of forming an alignment film, the method of manufacturing an optical element, and the optical element according to the embodiment of the present invention have been described in detail. However, the present invention is not limited to the above-described examples, and various improvements and modifications can be made within a range not departing from the scope of the present invention.

### EXAMPLES

Hereinafter, the characteristics of the present invention will be described in detail using examples. Materials, chemicals, used amounts, material amounts, ratios, treatment details, treatment procedures, and the like shown in the following examples can be appropriately changed within a range not departing from the scope of the present invention. Accordingly, the scope of the present invention is not limited to the following specific examples.

### Example 1

### (Manufacturing of Focusing Element X)

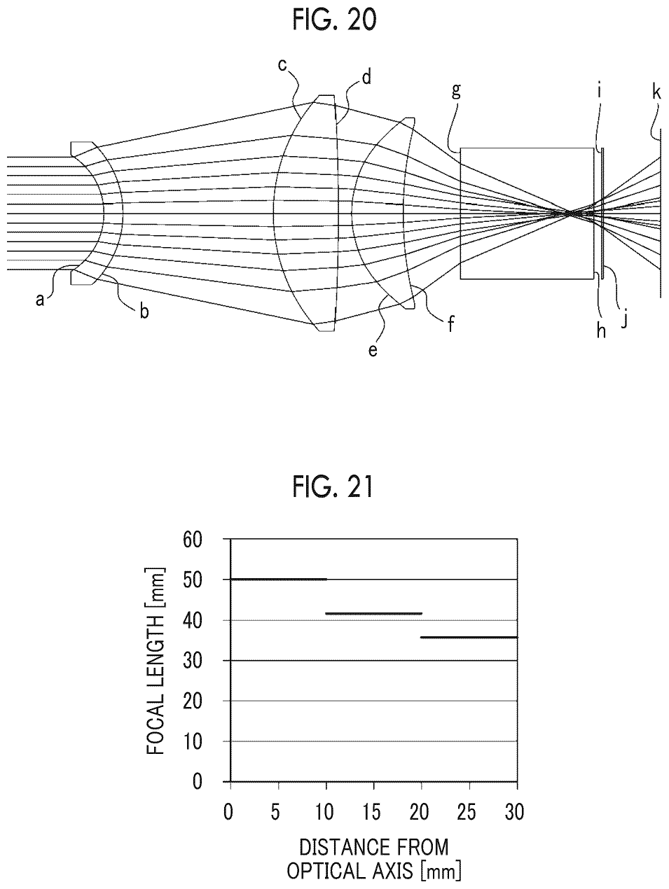

A focusing element having the same configuration as the focusing element 58 shown in FIG. 6 consisting of three lenses of a negative meniscus lens (lens 1), a biconvex lens (lens 2) having different curvatures, and a positive meniscus lens (lens 3) having an aspherical surface as shown in FIG. 20 was manufactured.

The arrangement order of the lenses was the lens 1, the lens 2, and the lens 3 from the upstream side. Accordingly, a beam combiner element, a polarization conversion element, and a non-exposed photo-alignment film (exposure surface) were positioned in this order downstream of the lens 3.

Further, although not shown in the drawing, a lens stop was provided upstream of the lens 1. The diameter of the lens stop was 60.0 mm.

The focusing element was designed such that, in the lens stop, the lenses, the optical element, and exposure surface, a curvature radius R of each of optical surfaces a to k, an interval D on an optical axis between each of the optical surfaces and a surface adjacent to optical surface on the downstream side (exposure surface side), and a refractive index N at a wavelength of 355 nm were numerical values shown in Table 1 below. The optical surface (emission surface) of the lens stop is shown as an optical surface 0. In addition, in the lens 3 as the positive meniscus lens, the incident surface, that is, the optical surface e is an aspherical surface.

TABLE 1

| | | Curvature Radius R | Interval D | Refractive Index N | Forming Material |
|---|---|---|---|---|---|
| Stop | Optical Surface 0 | 0.0000 | 30.00 | | |
| Lens 1 | Optical Surface a | −36.4701 | 10.00 | 1.53817 | H-K9L.NHG |
| | Optical Surface b | −52.6458 | 78.90 | | |
| Lens 2 | Optical Surface c | 94.5339 | 33.76 | 1.53817 | H-K9L.NHG |
| | Optical Surface d | −1055.2392 | 6.93 | | |
| Lens 3 | Optical Surface e | 58.3680 | 27.10 | 1.53817 | H-K9L.NHG |
| | Optical Surface f | 195.9158 | 30.00 | | |
| Beam Combiner | Optical Surface g | 0.0000 | 70.00 | 1.47609 | Si0₂ |
| | Optical Surface h | 0.0000 | 9.00 | | |
| Polarization Conversion Element | Optical Surface i | 0.0000 | 1.00 | 1.47609 | Si0₂ |
| | Optical Surface j | 0.0000 | 25.00 | | |
| Exposure Surface | Optical Surface k | 0.0000 | 0.00 | | |

The optical surface e is an aspherical surface.

As described above, the lens 3 is an aspherical lens, and the optical surface e (incident surface) is an aspherical surface.

The lens 3 was designed such that the aspherical surface had an aspherical coefficient shown in Table 2 below.

TABLE 2

| | |
|---|---|
| K | 1.000000000000E+00 |
| A3 | 4.671348572416E−05 |
| A4 | 5.272908371892E−05 |
| A5 | −9.060428982275E−06 |
| A6 | 5.977957128431E−07 |
| A7 | −2.027632634091E−08 |
| A8 | 3.772555132489E−10 |
| A9 | −3.667266211701E−12 |
| A10 | 1.455381336087E−14 |

$$Z = \frac{C}{1 + \sqrt{1 - K \times {( C \times h )}^{2}}} \times {h}^{2} + {\sum }_{i = 3}^{10} {A}_{i} \times {h}^{i}$$

In the expression,
Z represents an aspherical surface depth, that is, the length of a perpendicular line from a point on the aspherical surface at a height h to a plane perpendicular to an optical axis in contact with an aspherical surface apex, h represents the height, that is, the distance from the optical axis at a certain point on the lens surface, and
C represents a reciprocal of a paraxial curvature radius, and
K and Ai represent aspherical coefficients.

Due to the above-described design, a focusing element X having a focal length profile shown on the left side of FIG. 5 was manufactured.

The ratio “fLmax/fLmin” of the maximum value fLmax to the minimum value fLmin of the focal length fL represented by “fL=Ds/Sine” in FIG. 2 was more than 1.4.

### (Formation of Alignment Film)

The following coating liquid for forming an alignment film was continuously applied to a glass substrate having a thickness of 1.1 mm formed using a #2 wire bar. The support on which the coating film of the coating liquid for forming an alignment film was formed was dried using a hot plate at 60° C. for 60 seconds. As a result, a non-exposed photo-alignment film was formed.

Coating Liquid for forming Alignment Film

| | |
|---|---|
| Material A for photo-alignment | 1.00 part by mass |
| Water | 16.00 parts by mass |
| Butoxyethanol | 42.00 parts by mass |
| Propylene glycol monomethyl ether | 42.00 parts by mass |

Material A for Photo-Alignment-

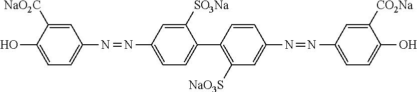

### (Exposure of Alignment Film)

The non-exposed photo-alignment film was exposed using the exposure system shown in FIG. 1 to form an alignment film having an alignment pattern. The exposure time was 4 minutes. As the exposure time, the shortest exposure time for which liquid crystal was able to be aligned in a case where an optically-anisotropic layer was provided on the manufactured alignment film was determined.

As the light source, a laser light source that has an output of 100 mW/m² and emits laser light having a wavelength of 355 nm was used. In addition, an optical path adjustment optical system shown in FIG. 1 including two actuated mirrors and two detectors was operated to perform a feedback control (Table 3, Optical Path Adjustment) for adjusting the angles of the actuated mirrors based on the detection result of the laser light, and thus the optical path of the laser light was stabilized.

The exposure system shown in FIG. 1 includes a beam expander element on the light source side of the beam splitter element. The beam expander element expanded the beam diameter such that the beam diameter of the beam incident into the beam splitter element was 60 mmϕ.

In each of the beam expander element, the beam splitter element, the beam combiner element, the focusing element, and the polarization conversion element, an antireflection treatment was performed on the incident surface and the emission surface such that a surface reflectivity (Table 3, Surface Reflectivity) with respect to light having a wavelength of 355 nm was 0.3% or less. In the focusing element, an antireflection treatment was performed on all the lenses.

In the exposure system, the optical elements were disposed such that an optical path length (Table 3, Optical Path Length) between the beam splitter element and the beam combiner element was 450 mm.

In measurement using an illuminance meter, in this example, the maximum value/minimum value (Table 3, In-Plane Intensity Ratio) of light emitted from the beam combiner element was 17 times at the position in the plane (exposure surface) of the alignment film as a measurement target.

In addition, in a case where parallel light was caused to be incident into the focusing element, a maximum angle (Table 3, Incidence Angle) with respect to the optical axis of light emitted from the beam combiner element was 36.5°.

### (Formation of Optically-Anisotropic Layer (Liquid Crystal Layer))

As liquid crystal compositions forming first, second, and third optically-anisotropic layers, the following compositions B-1, B-2, and B-3 were prepared.

### Composition B-1

| | |
|---|---|
| Liquid crystal compound L-1 | 100.00 parts by mass |
| Chiral agent C-3 | 0.23 parts by mass |
| Chiral agent C-4 | 0.82 parts by mass |
| Polymerization initiator (IRGACURE OXE01, manufactured by BASF SE) | 1.00 part by mass |
| Leveling agent T-1 | 0.08 parts by mass |
| Methyl ethyl ketone | 1050.00 parts by mass |

Liquid Crystal Compound L-1 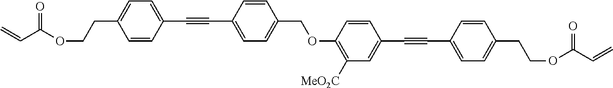 [SMILES: C=CC(=O)OCCc1ccc(C#Cc2ccc(COc3ccc(C#Cc4ccc(CCOC(=O)C=C)cc4)cc3C(=O)OC)cc2)cc1]
Chiral Agent C-3 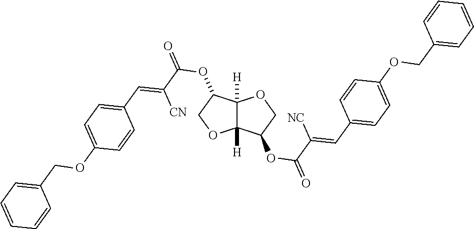 [SMILES: N#C/C(=C\c1ccc(OCc2ccccc2)cc1)C(=O)O[C@H]1CO[C@@H]2[C@@H]1OC[C@H]2OC(=O)/C(C#N)=C/c1ccc(OCc2ccccc2)cc1]
Chiral Agent C-4 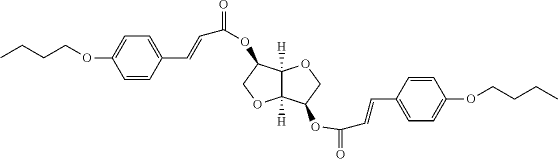 [SMILES: CCCCOc1ccc(/C=C/C(=O)O[C@@H]2CO[C@H]3[C@@H]2OC[C@H]3OC(=O)/C=C/c2ccc(OCCCC)cc2)cc1]
Leveling Agent T-1

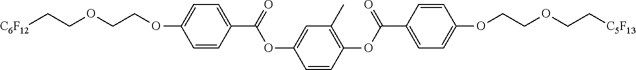

### Composition B-2

| | | |
|---|---|---|
| Liquid crystal compound L-1 | 100.00 | parts by mass |
| Chiral agent C-3 | 0.54 | parts by mass |
| Chiral agent C-4 | 0.62 | parts by mass |
| Polymerization initiator (IRGACURE OXE01, | 1.00 | part by mass |
| manufactured by BASF SE) | | |
| Leveling agent T-1 | 0.08 | parts by mass |
| Methyl ethyl ketone | 1050.00 | parts by mass |

### Composition B-3

| | | |
|---|---|---|
| Liquid crystal compound L-1 | 100.00 | parts by mass |
| Chiral agent C-3 | 0.48 | parts by mass |
| Polymerization initiator (IRGACURE OXE01, | 1.00 | part by mass |
| manufactured by BASF SE) | | |
| Leveling agent T-1 | 0.08 | parts by mass |
| Methyl ethyl ketone | 1050.00 | parts by mass |

First, a first optically-anisotropic layer was formed by applying multiple layers of the composition B-1 to the alignment film.

The application of the multiple layers refers to repetition of the following processes including: manufacturing a first liquid crystal immobilized layer by applying the first layer-forming composition B-1 to the alignment film, heating the composition B-1, cooling the composition B-1, and irradiating the composition B-1 with ultraviolet light for curing; and manufacturing a second or subsequent liquid crystal immobilized layer by applying the second or subsequent layer-forming composition B-1 to the formed liquid crystal immobilized layer, heating the composition B-1, cooling the composition B-1, and irradiating the composition B-1 with ultraviolet light for curing as described above. Even in a case where the liquid crystal layer was formed by the application of the multiple layers such that the total thickness of the optically-anisotropic layer was large, the alignment direction of the alignment film was reflected from a lower surface of the optically-anisotropic layer to an upper surface thereof.

Specifically, in order to form the first layer of the first optically-anisotropic layer, the composition B-1 was applied to the alignment film, and the coating film was heated on a hot plate at 80° C. Next, the coating film was irradiated with ultraviolet light having a wavelength of 365 nm using an LED-UV exposure device. Next, the coating film heated on a hot plate at 80° C. was irradiated with ultraviolet light having a wavelength of 365 nm at an irradiation dose of 300 mJ/cm² using a high pressure mercury lamp in a nitrogen atmosphere. As a result, the alignment of the liquid crystal compound was immobilized.

Regarding the second or subsequent liquid crystal layer, the composition was applied to the first liquid crystal immobilized layer, and then a liquid crystal immobilized layer was manufactured under the same conditions as described above. This way, by repeating the application multiple times until the total thickness reached a desired film thickness, the first optically-anisotropic layer was formed.

In the first optically-anisotropic layer, finally, Δn₅₅₀×thickness (Re(550)) of the liquid crystal was 160 nm, and the twisted angle of the liquid crystal compound L-1 in the thickness direction was left-twisted and 80° (−80°).

Next, a second optically-anisotropic layer was formed using the same method as that of the first optically-anisotropic layer, except that the composition B-2 was applied to the first optically-anisotropic layer such that the total thickness was changed to a desired film thickness.

In the second optically-anisotropic layer, finally, Δn₅₅₀×thickness (Re(550)) of the liquid crystal was 355 nm, and the twisted angle of the liquid crystal compound L-2 in the thickness direction was left-twisted and 4° (−4°).

Next, a third optically-anisotropic layer was formed using the same method as that of the first optically-anisotropic layer, except that the composition B-3 was applied to the second optically-anisotropic layer such that the total thickness was changed to a desired film thickness.

In the third optically-anisotropic layer, finally, Δn₅₅₀×thickness (Re(550)) of the liquid crystal was 160 nm, and the twisted angle of the liquid crystal compound L-2 in the thickness direction was right-twisted and 80° (−80°).

This way, an optical element (liquid crystal diffractive lens) according to Example 1 including the first to third optically-anisotropic layers was manufactured.

In a case where the obtained optical element was observed with an optical microscope, it was verified that the optically-anisotropic layer had a concentric liquid crystal alignment pattern shown in FIG. 3 having a diameter of 60 mm that radially included an alignment pattern where an optical axis derived from the liquid crystal compound continuously rotated in one direction. Note that it was verified that, in the alignment pattern where the optical axis continuously rotated in the one direction, the degree of the decrease in the length of the single period over which the optical axis rotated by 180° was not an inverse-proportional monotonic decrease and regions where the focal length varied depending on the change in the length of the single period in a plane of the optical element were formed.

In a case where a focal length profile of the manufactured optical element was verified from a profile (pitch profile) of the change in the single period of the liquid crystal alignment pattern observed with the optical microscope, the focal length profile was as shown on the right of FIG. 5 where the focal length continuously changed.

### Example 2

An optical element according to Example 2 was manufactured using the same method as that of the preparation of the optical element in Example 1, except that the optical path length (Table 3, Optical Path Length) between the beam splitter element and the beam combiner element was 1000 mm and the exposure time was 10 minutes.

### Example 3

An optical element according to Example 3 was manufactured using the same method as that of the preparation of the optical element in Example 1, except that in each of the beam expander element, the beam splitter element, the beam combiner element, the focusing element, and the polarization conversion element, the antireflection treatment performed on the incident surface and the emission surface was changed such that a surface reflectivity (Table 3, Surface Reflectivity) with respect to light having a wavelength of 355 nm was 0.7% and the exposure time was 10 minutes.

### Example 4

An optical element according to Example 4 was manufactured using the same method as that of the preparation of the optical element in Example 1, except that a fixed mirror was used without performing the feedback control (Table 3, optical path adjustment) of the optical path of the light beam M by the optical path adjustment optical system and the exposure time was 15 minutes.

### Example 5

An optical element according to Example 5 was manufactured using the same method as that of the preparation of the optical element in Example 1, except that a focusing element (focusing element Y) was designed such that the ratio “fLmax/fLmin” was 1.2 by changing the aspherical coefficient of the aspherical surface of the lens 3 forming the focusing element X and the exposure time was 10 minutes.

In the same measurement as that of Example 1, the maximum value/minimum value (Table 3, In-Plane Intensity Ratio) of light emitted from the beam combiner element was 35 times at the position in the plane of the alignment film.

### Comparative Example 1

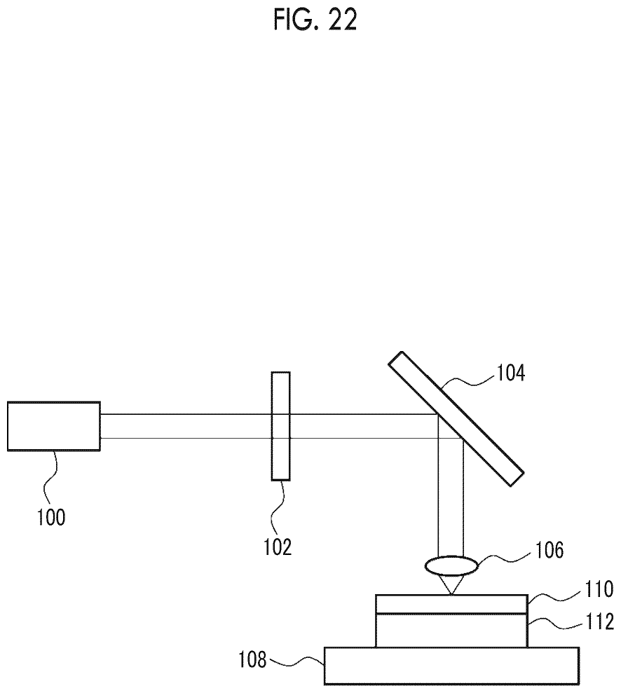

An optical element according to Comparative Example 1 was manufactured using the same method as that of Example 1, except that the non-exposed photo-alignment film was exposed using the above-described direct drawing exposure method shown in FIG. 22.

The non-exposed photo-alignment film was exposed, that is, drawn such that the alignment pattern formed on the obtained alignment film was the same as the alignment pattern of Example 1. Accordingly, the focal length profile of the obtained optical element was the same as that of Examples 1 to 5.

In this example, a time of 3 hours or longer was required to expose (draw) the alignment film.

### Comparative Example 2

In the exposure system shown in FIG. 1, a typical condenser lens (positive lens) where the focal length did not vary in a plane was used as the focusing element.

As the focusing element, three kinds of focusing elements having different focal lengths were prepared. These focusing elements were sequentially applied to the exposure system shown in FIG. 1 and were dividedly exposed three times through a mask to manufacture an alignment film. Next, an optically-anisotropic layer was formed using the same method as that of Example 1 to manufacture an optical element.

The exposure time per time was 4 minutes (4 minutes×3 times). In addition, the ratio “fLmax/fLmin” was adjusted to 1.4 as in Example 1.

In a case where the focal length profile of the manufactured optical element was verified using the same method as that of Example 1, the focal length profile was as shown in FIG. 21.

Regarding each of the manufactured optical elements, a cross section taken along the thickness direction along the one direction in which the optical axis derived from the liquid crystal compound continuously rotated was observed with an SEM.

As a result, all the optical elements included three optically-anisotropic layers as shown in FIG. 19, and the tilt directions of the bright and dark lines (the bright lines and the dark lines) in the upper and lower optically-anisotropic layers were opposite to each other, and the tilt direction of the bright and dark lines in the middle optically-anisotropic layer substantially matched with the thickness direction.

### Evaluation

Regarding the manufactured optical elements, a boundary region and aligning properties were evaluated.

### <Boundary Region>

Whether or not a boundary region was present between the regions where the focal length varied in the manufactured optical element was verified with a polarization microscope.

### <Aligning Properties>

The concentric liquid crystal alignment pattern of the manufactured optical element was observed with a polarization microscope from a center part to an end part, and the alignment state of the liquid crystal compound was evaluated based on the following evaluation standards.
A: The concentric liquid crystal alignment pattern was in an excellent alignment state from the center part to the end part
B: In the concentric liquid crystal alignment pattern, the alignment of the center part was excellent, but alignment defects were observed in the end part
C: In the concentric liquid crystal alignment pattern, a region where the liquid crystal compound was not aligned was observed

The results are shown in Table 3 below.

TABLE 3

| | Example 1 | Example 2 | Example 3 | Example 4 | Example 5 | | Comparative Example 2 |
|---|---|---|---|---|---|---|---|
| Exposure Method of | Interference | Interference | Interference | Interference | Interference | Comparative Example 1 | Interference |
| Alignment Film | Exposure | Exposure | Exposure | Exposure | Exposure | Direct Drawing | Exposure + Mask |
| | X | X | X | X | Y | — | Z |
| fLmax/fLmin | 1.4 | 1.4 | 1.4 | 1.4 | 1.2 | — | 1.4 |
| In-Plane Intensity Ratio | 17 | 17 | 17 | 17 | 35 | — | — |
| Incidence Angle | 36.5° | 36.5° | 36.5° | 36.5° | 36.5° | — | — |
| Optical Path Length | 450 mm | 1000 mm | 450 mm | 450 mm | 450 mm | — | 450 mm |
| Surface Reflectivity | 0.3% or less | 0.3% or less | 0.7% | 0.3% or less | 0.3% or less | — | 0.3% or less |
| Optical Path | Performed | Performed | Performed | Not | Performed | — | Performed |
| Adjustment | | | | Performed | | | |
| Exposure Time | 4 Minutes | 10 Minutes | 10 Minutes | 15 Minutes | 10 Minutes | 3 Hours~ | 4 Minutes × 3 Times |
| Boundary Region | None | None | None | None | None | None | Present |
| Aligning Properties | A | A | A | A | A | B | C |

As shown in Table 3, in the optical elements according to Examples 1 to 5 where the interference exposure was performed using the focusing element having the focal length profile where the focal length was not constant in the plane direction in the exposure system shown in FIG. 1, the boundary region was not present between the regions where the focal length varied in the liquid crystal alignment pattern, and the aligning properties were also excellent. In addition, the exposure time was also within 15 minutes.

In particular, in Example 1 that satisfied all the preferable aspects from the viewpoints of the ratio maximum intensity/minimum intensity (in-plane intensity ratio) in the plane of the alignment film, the optical path length between the beam splitter element and the beam combiner element, the surface reflectivity on the incident surface and the reflecting surface of each of the optical elements, and the stabilization of the optical path of the laser light source by the feedback control (optical path adjustment), as compared to Examples 2 to 4, the alignment was able to be performed within a shorter period of exposure time, which was excellent from the viewpoint of productivity and the like.

On the other hand, in Comparative Example 1 using the direct drawing exposure method (direct drawing), a time of 3 hours or longer was required to form the alignment pattern of the alignment film, and alignment defects were observed in the end part of the concentric liquid crystal alignment pattern.

In addition, in Comparative Example 2 where the exposure (interference exposure+masking) by masking was performed by using the exposure system shown in FIG. 1 where the typical positive lens was replaced as the focusing element, a boundary region was observed between the regions where the focal length varied, and a region where the liquid crystal compound was not aligned was observed in the boundary region.

In the optical elements manufactured in Example 1, Comparative Example 1, and Comparative Example 2, the ratio “fGmax/fGmin” of the maximum value and the minimum value of the focal length, the ratio Rmax of the zero-order light, and the maximum ratio Xmax of the noise light were measured using the methods shown in FIGS. 16 to 18.

As the measurement light, laser light having a wavelength of 530 nm was used. In addition, as the photodetector, a power meter including photodiodes was used, and was disposed at a position of 30 cm from the optical element as a measurement target.

As a result, in the optical element according to Example 1, the focal length continuously changed in the direction from the center toward the outer side of the concentric circle,
the ratio “fGmax/fGmin” was 1.4,
the ratio Rmax of the zero-order light was 0.7%,
the maximum ratio Xmax of the noise light was less than 0.1%, and the zero-order light and the noise light were not sufficiently suppressed.

In addition, in the optical element according to Comparative Example 1 manufactured by the direct drawing, the focal length continuously changed in the direction from the center toward the outer side of the concentric circle,
the ratio “fGmax/fGmin” was 1.4,
the ratio Rmax of the zero-order light was 3.5%,
the maximum ratio Xmax of the noise light was 3.5%, and the intensities of the zero-order light and the noise light were high.

Further, in the optical element according to Comparative Example 2 manufactured by the interference exposure using a mask, there was no region where the focal length continuously changed in the direction from the center toward the outer side of the concentric circle,
the ratio “fGmax/fGmin” was 1.4,
the ratio Rmax of the zero-order light was 6.0%,
the maximum ratio Xmax of the noise light was 5.0%, and the intensities of the zero-order light and the noise light were high.

Δn of the liquid crystal layer was measured with the above-described method using Axoscan (manufactured by Axometrix Inc.) and an SEM. As a result, in all the optical elements, Δn of the liquid crystal layer was 0.24.

Further, a commercially available head-mounted display (manufactured by HTC Corporation, VIVE Flow) was disassembled, the manufactured optical element was bonded to a liquid crystal display, and the head-mounted display was assembled again. In this state, an image was displayed to evaluate the occurrence of a ghost and multiple images in the displayed image by visual inspection.

As a result, in the head-mounted display including the optical element according to Example 1, the ghost was in an allowable range, and the multiple images were not recognized.

On the other hand, in the head-mounted displays including the optical elements according to Comparative Examples 1 and 2, the ghost and multiple images were easily recognized.

Regarding the optical elements manufactured in Examples 2 to 5, the same measurement was performed.

As a result, in all the optical elements, the ratio “fGmax/fGmin” was more than 1.1, the ratio Rmax of the zero-order light was 3% or less, the maximum ratio Xmax of the noise light was in a range of 3% or less, the ghost was in an allowable range, and the multiple images were not recognized or were in an allowable range.

As can be seen from the above results, the effects of the present invention are obvious.

The present invention can be suitably used for manufacturing optical elements forming various optical devices.

### EXPLANATION OF REFERENCES

10, 36: optical element
20: substrate
24: alignment film
26, 26A: optically-anisotropic layer
30: liquid crystal compound
30A: optical axis
34, 34A: (cholesteric) liquid crystal layer
42: bright line
44: dark line
52, 100: light source
54: beam splitter element
56a, 56b, 76, 104: mirror
58: focusing element
60: beam combiner element
60a: first surface
60b: second surface
62: polarization conversion element
70: beam expander element
72: optical path adjustment optical system
74a, 74b: actuated mirror
78a, 78b: detector
102: polarization conversion element
106: condenser lens
108: x-y stage
110: non-exposed photo-alignment film
112: glass substrate
M: light beam
M1: first light beam
M2: second light beam
LS: light source
S: optical element

What is claimed is:

1. An exposure system comprising:
a light source;
a beam splitter element that splits light emitted from the light source;
a beam combiner element that includes a first surface and a second surface and emits light obtained by combining light transmitted through the first surface and light reflected from the second surface, the first surface allowing incidence of one light component split by the beam splitter element and transmission of at least a part of the incidence light, and the second surface allowing incidence of another light component split by the beam splitter element and reflecting at least a part of the incidence light; and
a focusing element that focuses light and is provided on at least one of an optical path of first light incident into the first surface of the beam combiner element or an optical path of second light incident into the second surface of the beam combiner element,
wherein at least one of the focusing elements is a focal point-variable focusing element where a focal length fL continuously changes in a direction orthogonal to an optical axis, and a ratio “fLmax/fLmin” of a maximum value fLmax to a minimum value fLmin of the focal length fL is more than 1.1.

2. The exposure system according to claim 1, further comprising:
a beam expander element that is provided at at least one position of a position between the light source and the beam splitter element, a position between the beam splitter element and the beam combiner element, or a position where light is not focused.

3. The exposure system according to claim 1,
wherein in the focal point-variable focusing element, a profile of the focal length that continuously changes in the direction orthogonal to the optical axis has one or more extreme values.

4. The exposure system according to claim 1,
wherein the focal point-variable focusing element includes a plurality of lenses.

5. The exposure system according to claim 1,
wherein the focal point-variable focusing element includes at least one of an aspherical lens or a cylinder lens.

6. The exposure system according to claim 1,
wherein in a case where parallel light is incident into the focal point-variable focusing element, at least a part of light emitted from the beam combiner element has an angle of 15° or more with respect to the optical axis of the focal point-variable focusing element.

7. The exposure system according to claim 1,
wherein a ratio maximum value/minimum value of a maximum value to a minimum value of an intensity of light in the direction orthogonal to the optical axis of the focal point-variable focusing element is 25 times or less on an exposure surface.

8. The exposure system according to claim 1,
wherein an optical path length between the beam splitter element and the beam combiner element is 800 mm or less.

9. The exposure system according to claim 1,
wherein one or more optical elements that are present have a surface reflectivity of 0.5% or less with respect to light emitted from the light source.

10. The exposure system according to claim 1,
wherein the light source emits light having a wavelength of 320 to 410 nm.

11. The exposure system according to claim 1, further comprising:
at least one adjustment unit of an adjustment unit that detects an optical path of light emitted from the light source at a position upstream of the beam splitter element and adjusts the optical path of the light based on a detection result of the optical path of the light or an adjustment unit that detects an interference fringe generated by interference of combined light at a position downstream of the beam combiner element and adjusts an optical path of at least one of light components split by the beam splitter element based on a detection result of the interference fringe.

12. A method of forming an alignment film, the method comprising:
exposing a coating film that includes a compound having a photo-aligned group using the exposure system according to claim 1.

13. A method of manufacturing an optical element, the method comprising:
a step of applying a composition including a liquid crystal compound to an alignment film formed using the method of forming an alignment film according to claim 12 and drying the applied composition.

14. The method of manufacturing an optical element according to claim 13,
wherein the composition includes a chiral agent.

15. An optical element that diffracts incidence light and emits the diffracted light, the optical element comprising:
a liquid crystal layer that concentrically has a liquid crystal alignment pattern where an orientation of an optical axis derived from a liquid crystal compound changes while continuously rotating in at least one in-plane direction,
wherein in a case where a length over which the orientation of the optical axis derived from the liquid crystal compound in the liquid crystal alignment pattern of the liquid crystal layer rotates by 180° in a plane is set as a single period, a length of the single period in the liquid crystal alignment pattern gradually changes in the one direction,
in the optical element, a focal length fG continuously changes in a direction from a center toward an outer side of the concentric circle,
a ratio “fGmax/fGmin” of a maximum value fGmax to a minimum value fGmin of the focal length fG is more than 1.1,
at a position where a ratio of an intensity of zero-order light to an intensity of first-order light in a plane of the optical element is the maximum, in a case where the ratio of the intensity of the zero-order light to the intensity of the first-order light is represented by Rmax, the ratio Rmax is 3% or less, and
in a case where a ratio of an intensity of a diffracted light component having a maximum intensity among diffracted light components having diffraction angles less than a diffraction angle of first-order light to an intensity of first-order light is represented by Xmax, the ratio Xmax is 3% or less at a position where the ratio Xmax is the maximum in a plane of the optical element.

16. The optical element according to claim 15,
wherein Δn of the liquid crystal layer is 0.2 to 0.5.

17. The optical element according to claim 15, comprising:
a plurality of the liquid crystal layers,
wherein at least two of the liquid crystal layers include regions where tilts of bright and dark lines in cross sectional images obtained by observing cross sections taken in a thickness direction along the one direction with a scanning electron microscope are different from each other.

18. An optical element according to claim 17, comprising:
at least three liquid crystal layers including
a first liquid crystal layer where the bright and dark lines are tilted with respect to a main surface,
a second liquid crystal layer where a tilt direction of the bright and dark lines is opposite to that of the first liquid crystal layer, and
a third liquid crystal layer that is provided between the first liquid crystal layer and the second liquid crystal layer and where an angle of the bright and dark lines with respect to a main surface is more than those of the first liquid crystal layer and the second liquid crystal layer.

19. The exposure system according to claim 2,
wherein in the focal point-variable focusing element, a profile of the focal length that continuously changes in the direction orthogonal to the optical axis has one or more extreme values.

20. The exposure system according to claim 2,
wherein the focal point-variable focusing element includes a plurality of lenses.
